(19) United States
(12) Patent Application Publication
(10) Pub. No.: US 2026/0110735 A1
(43) Pub. Date: Apr. 23, 2026

(54) INTEGRATED PROTOCOL ANALYZER CONFIGURED WITHIN AUTOMATED TEST EQUIPMENT (ATE) HARDWARE WITH SIDEBAND AND SYSTEM EVENT TRIGGERING AND MEMORY POOLING

(71) Applicant: Advantest Corporation, Tokyo (JP)

(72) Inventors: Michael Jones, San Jose, CA (US); Jesse Hobbs, San Jose, CA (US); Harris Chou, San Jose, CA (US)

(21) Appl. No.: 18/921,766

(22) Filed: Oct. 21, 2024

(51) Int. Cl. G01R 31/319

(52) U.S. Cl. CPC G01R 31/31917

(57) ABSTRACT

Embodiments of the present invention provide a test system that includes an integrated protocol analyzer (IPA) and wherein memory allocated to different DUTs can be pooled for improved capture depth during testing. The IPA also monitors one or more sideband communication channels (or for system events) and can advantageously trigger a response by the test system (e.g., the capturing and/or filtering of data) during device testing based on prescribed sideband data or prescribed system events. The sideband channel can also be used to transmit commands and signals generated by a sideband automatic pattern generator (APG) of an FPGA in communication with a DUT to test or configure the DUT. The sideband channel can be monitored continuously to identify signals, commands, or other data that trigger certain responses by the FPGA or other test system components. The sidebands are typically implemented using dedicated input/output pins of the DUT and the FPGA.

### CROSS-REFERENCE TO RELATED APPLICATIONS

The present invention is related to U.S. patent application Ser. No. 16/521,174 filed on Jul. 24, 2019 and issued as U.S. Pat. No. 10,948,540, which is incorporated herein by reference in its entirety.

### FIELD OF THE INVENTION

The present disclosure relates generally to the field of electronic device testing systems and more specifically to the field of electronic device testing equipment for testing devices under test (DUTs).

### BACKGROUND OF THE INVENTION

Automated test equipment (ATE) can be any testing assembly that performs a test on a semiconductor device or electronic assembly. ATE assemblies may be used to execute automated tests that quickly perform measurements and generate test results that can then be analyzed. An ATE assembly may be anything from a computer system coupled to a meter, to a complicated automated test assembly that may include a custom, dedicated computer control system and many different test instruments that are capable of automatically testing electronics parts and/or semiconductor wafer testing, such as system-on-chip (SOC) testing or integrated circuit testing. ATE systems both reduce the amount of time spent on testing devices to ensure that the device functions as designed and serve as a diagnostic tool to determine the presence of faulty components within a given device before it reaches the consumer.

FIG. 1 is a schematic block diagram of a conventional automatic test equipment body 100 for testing certain typical DUTs e.g. a semiconductor memory device such as a DRAM. The ATE includes an ATE body 100 with hardware bus adapter sockets 110A-110N. Hardware bus adapter cards 110A-110N specific to a particular communication protocol, e.g. PCIe, USB, SATA, SAS etc., connect to the hardware bus adapter sockets provided on the ATE body and interface with the DUTs via cables specific to the respective protocol. The ATE body 100 also includes a tester processor 101 with an associated memory 108 to control the hardware components built into the ATE body 100 and to generate the commands and data necessary to communicate with the DUTs being tested through the hardware bus adapter cards. The tester processor 101 communicates with the hardware bus adapter cards over system bus 130. The tester processor may be programmed to include certain functional blocks including a pattern generator 102 and a comparator 106. Alternatively, the pattern generator 102 and comparator 106 may be hardware components mounted on an expansion or adapter card that plug into the ATE body 100.

The ATE body 100 tests the electrical functions of the DUTs 112A-112N connected to the ATE body 100 through hardware bus adapters plugged into the hardware bus adapter sockets of the ATE body 100. Accordingly, the tester processor 101 is programmed to communicate the test programs to be executed on the DUTs using the protocol unique to the hardware bus adapters. Meanwhile, the other hardware components built into the ATE body 100 communicate signals with each other and with the DUTs according to test programs operating in the tester processor 101.

The test program run by the tester processor 101 may include a function test which involves writing input signals created by the pattern generator 102 to the DUTs, reading out the written signals from the DUTs and using the comparator 106 to compare the output with the expected patterns. If the output does not match the input, the tester processor 101 will identify the DUT as being defective. For example, if the DUT is a memory device such as a DRAM, the test program will write data generated by the pattern generator 102 to the DUT using a Write Operation, read data from the DRAM using a Read Operation and compare the expected bit pattern with the read pattern using the comparator 106.

In conventional systems, the tester processor 101 needs to contain the functional logic blocks to generate the commands and test patterns used in testing the DUTs, such as the pattern generator 102 and the comparator 106, programmed in software directly on the processor. However, in some instances certain functional blocks such as the comparator 106 may be implemented on a field programmable gate array (FPGA), which is an application specific integrated circuit (ASIC) type semiconductor device that can program logic circuits according to a user's demand.

The FPGAs used in conventional systems rely on the tester processor 101 to transfer the commands and test patterns to the FPGA, which the FPGA in turn relays over to the DUTs. Because the tester processor, and not the FPGA, is responsible for generating the commands and test patterns, the number and type of DUTs that can be tested with a given ATE body is limited by the processing capabilities and programming of the tester processor. Where the tester processor generates all the commands and test patterns, bandwidth constraints on the system bus 130 connecting the tester processor to the various hardware components, including any FPGA devices and hardware bus adapter sockets, also places an upper limit on the number of DUTs that can tested simultaneously.

Also, in conventional systems, the communication protocol used to communicate with the DUTs is fixed because the hardware bus adapter cards that plug into the ATE body 100 are single purpose devices that are designed to communicate in only one protocol and cannot be reprogrammed to communicate in a different protocol. For example, an ATE body configured to test PCIe devices will have hardware bus adapter cards plugged into the body that support only the PCIe protocol. In order to test DUTs supporting a different protocol, e.g., Universal Flash Storage (UFS) the user would ordinarily need to replace the PCIe hardware bus adapter cards with bus adapter cards supporting the UFS protocol. Unless the PCIe hardware bus adapter cards are physically substituted with cards supporting the other protocol, such a system can only test DUTs that support the PCIe protocol. Thus, on the test floor, critical time is consumed replacing hardware bus adapter cards when DUTs running a different protocol from the one that the existing adapter cards support need to be tested.

Another drawback of conventional ATE systems relates to the test equipment required to test whether the ATE systems are communicating properly with the DUTs. Typically, ATE is used to test anywhere from one to several hundred devices under the test (DUTs) at the same time. In order to verify that the ATE is communicating properly with the DUTs, workbench equipment such as oscilloscopes and protocol analyzer can be used. These devices are typically bulky, cumbersome and inordinately expensive. Further, they require highly trained engineers to use and to interpret the data. As a result, these devices are not generally suitable for production facilities.

Protocol analyzers, for example, are passive diagnostic tools that collect, organize, and display protocol traffic occurring on a serial link. Protocol analyzers use large amounts of memory to store the traffic, typically many gigabytes. The stored traffic represents one of two forms of data: raw and protocol. In raw mode, the protocol analyzer saves the serial data bit for bit in its memory. In protocol mode, the protocol analyzer first decodes and descrambles the data prior to saving the data to memory. In both cases, the protocol analyzer uses a prohibitively large amount of memory to store all the diagnostic data for an engineer to be able to analyze.

Beyond the protocol data used to communicate with the DUTs during testing, some test systems use sideband communication channels, separate from the protocol data channels, to communicate additional information during testing in parallel with the protocol data. In other words, while protocol data (test data) is typically transmitted between test system components and DUTs during testing, a secondary channel (sideband channel) can be used concurrently to communicate other information, without interrupting the typical test activities being performed on the primary channel. Sideband channels are typically used to communicate relatively slow speed commands and signals such as reset signals, clock enable signals, low power mode commands, configuration commands and signals, wake signals free running clock reset signals, etc., from an FPGA or other test system component to a DUT. In some cases, sideband signals may be generated by the DUT and transmitted to the test system.

Unfortunately, existing approaches to device testing are unable to fully utilize the data transmitted over sideband channels during testing. For example, the sideband data may include important activity, signals, commands, or other information that is relevant to ongoing device testing, and this data is not able to be identified or analyzed in a timely manner using traditional test systems. While existing test systems may store large amounts of test data, including sideband data, for analysis at a later time, these systems are typically unable to analyze side band data in order to trigger collection and/or filtering of data during testing. Moreover, existing approaches to DUT testing fail to monitor protocol communication data for system events that may indicate potential issues during testing. Therefore, these test systems are unable to efficiently handle issues during testing without halting testing, analyzing test data, and addressing any detected issues before testing resumes. In other words, system events often cannot be detected and handled (e.g., debugged) efficiently using conventional test systems.

Current test systems also generate many system events during the testing process. A drawback of current systems is they do not provide a mechanism for triggering the capture and/or filtering of test data based on prescribed system events.

Another drawback of current test systems is that memory resources are often limited, and furthermore, unused memory resources allocated to a device are not able to be shared with other devices undergoing active testing. This shortage of memory resources often limits the depth of captured data; in other words, only so many test activities may be captured before memory becomes bottlenecked and further data cannot be captured without overwriting or erasing existing data.

### BRIEF SUMMARY OF THE INVENTION

Accordingly, a need exists for an integrated protocol analyzer (IPA) that can monitor and utilize sideband data during testing for improved test performance and efficiency, including the ability to pool memory resources for increased capture depth. Additionally, there is a need for an IPA that can monitor sideband data in real-time, and that can react (trigger) upon detection of certain data communicated over a sideband channel. For example, there is a strong desire for an IPA that can trigger the capturing and/or filtering of sideband data (and simultaneously protocol data) upon detection of certain sideband activity in order to save memory resources. In this way, the user can inspect the relationship between the sideband and the protocol data that is captured simultaneously. Moreover, there is a need for an IPA that can activate various triggers based on tester activity (e.g., a data mismatch), and more specifically, to enable triggering at a specific point of a sequence of operations/commands (e.g., a test sequence). There is also a need for an IPA that can pool memory resources that are allocated to particular DUTs that are not being tested or debugged by the IPA so that these resources can be made available for capturing test data at a greater depth for other DUTs being tested, thereby improving debugging efficiency and overall test throughput for the DUTs being tested.

According to one embodiment, the test system can trigger based on prescribed sideband information and sideband data can be captured during testing advantageously alongside protocol data, and the captured data can be filtered to eliminate unwanted information to preserve memory resources. In this case, of particular interest, the user can see the relationship between the sideband and the protocol data for debugging. In another embodiment, various triggers are activated based on tester activity (e.g., system events), and these triggers can be activated at a specific step of a test sequence. In another embodiment, the IPA can pool memory resources allocated to various DUTs (e.g., DUTs that are not being tested or debugged), and the pooled memory resources can be made available to other DUTs being actively tested, for example, to increase the amount of data that can be captured and stored by the FPGA during testing.

The following detailed description together with the accompanying drawings will provide a better understanding of the nature and advantages of the present invention.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIG. 1 is a schematic block diagram of a conventional automatic test equipment body for testing a typical device under test (DUT).

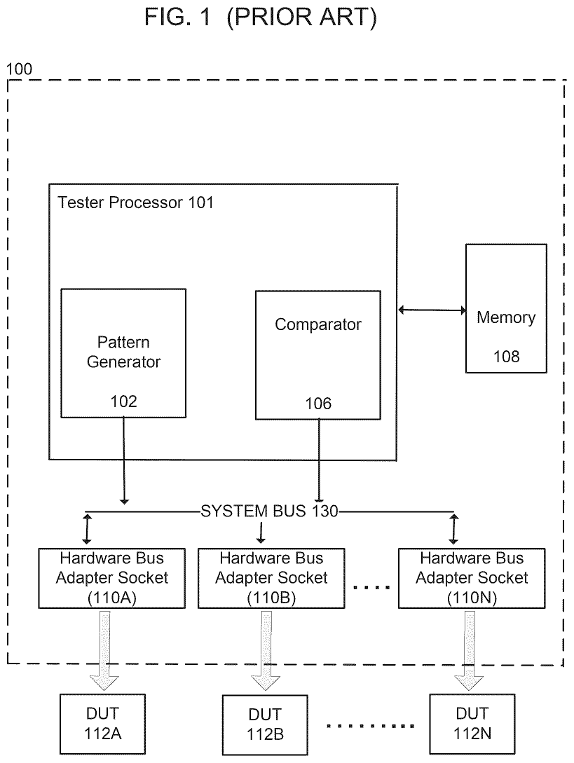

FIG. 2 is a high level schematic block diagram of the interconnections between the system controller, the site modules and the DUTs according to one embodiment of the present invention.

FIG. 3 is a detailed schematic block diagram of the site module and its interconnections with the system controller and the DUTs according to an embodiment of the present invention.

FIG. 4 illustrates a UFS device in communication with a UFS host.

FIG. 5 illustrates a tester system with an IPA that is configured into the tester hardware in accordance with an embodiment of the present invention.

FIG. 6 illustrates an exemplary output that can be displayed through the GUI to a user in accordance with an embodiment of the present invention.

FIG. 7 illustrates a flowchart of an exemplary computer implemented process for monitoring protocol data and command traffic during automated device testing in accordance with one embodiment of the present invention.

FIG. 8 illustrates a flowchart of an exemplary computer implemented process for programming an integrated protocol analyzer in a tester to collect and display information in accordance with one embodiment of the present invention.

FIG. 9 illustrates a block diagram with data flow of an exemplary sub-system for triggering and capturing based on sideband data using an IPA implemented on an FPGA for DUT testing in accordance with one embodiment of the present invention.

FIG. 10 illustrates a block diagram with data flow of an exemplary sub-system that uses a command sequencer implemented on exemplary FPGA to generate or provide a series of signals/commands for performing device testing that issues triggers based on system events in accordance with one embodiment of the present invention.

FIG. 11 illustrates a block and data flow diagram of an exemplary sub-system involving an FPGA having IPA storage and non-IPA storage for storing captured protocol data and/or data of sidebands using pooled memory resources for testing a DUT in accordance with one embodiment of the present invention.

FIG. 12 illustrates a block diagram of an exemplary FPGA coupled to a DUT for testing and debugging using sideband signals to operate and/or configure the DUT in accordance with one embodiment of the present invention.

FIG. 13 illustrates a flowchart of an exemplary process for monitoring and capturing data generated during testing for storage in a pooled memory including memory normally allocated to other DUTs in accordance with one embodiment of the present invention.

In the figures, elements having the same designation have the same or similar function.

### DETAILED DESCRIPTION OF THE INVENTION

Reference will now be made in detail to embodiments, examples of which are illustrated in the accompanying drawings. While the embodiments will be described in conjunction with the drawings, it will be understood that they are not intended to limit the embodiments. On the contrary, the embodiments are intended to cover alternatives, modifications and equivalents. Furthermore, in the following detailed description, numerous specific details are set forth in order to provide a thorough understanding. However, it will be recognized by one of ordinary skill in the art that the embodiments may be practiced without these specific details. In other instances, well-known methods, procedures, components, and circuits have not been described in detail as not to unnecessarily obscure aspects of the embodiments.

### NOTATION AND NOMENCLATURE SECTION

Some regions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing the terms such as “programming”, “monitoring,” “saving,” “performing,” “transmitting,” “receiving,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The description below provides a discussion of computers and other devices that may include one or more modules. As used herein, the term “module” or “block” may be understood to refer to software, firmware, hardware, and/or various combinations thereof. It is noted that the blocks and modules are exemplary. The blocks or modules may be combined, integrated, separated, and/or duplicated to support various applications. Also, a function described herein as being performed at a particular module or block may be performed at one or more other modules or blocks and/or by one or more other devices instead of or in addition to the function performed at the described particular module or block. Further, the modules or blocks may be implemented across multiple devices and/or other components local or remote to one another. Additionally, the modules or blocks may be moved from one device and added to another device, and/or may be included in both devices. Any software implementations of the present invention may be tangibly embodied in one or more storage media, such as, for example, a memory device, a floppy disk, a compact disk (CD), a digital versatile disk (DVD), or other devices that may store computer code.

The terminology used herein is for the purpose of describing particular embodiments only and is not intended to limit the scope of the present invention. As used throughout this disclosure, the singular forms “a,” “an,” and “the” include plural reference unless the context clearly dictates otherwise. Thus, for example, a reference to “a module” includes a plurality of such modules, as well as a single module, and equivalents thereof known to those skilled in the art.

### An Integrated Protocol Analyzer Configured Within Automated Test Equipment (Ate) Hardware

Embodiments of the present invention provide a tester system with an integrated protocol analyzer (IPA) that is configured into the tester hardware. In other words, the protocol analyzer uses the pre-existing hardware of the tester to collect diagnostic information about the tests. Further, the IPA uses triggering and filtering techniques to reduce the amount of memory it needs for collection. Also, the IPA of the present invention can collect critical information relevant to an engineer, selectively discard the less critical information, and report the critical information to the engineer in an organized and timely manner.

As discussed in more detail below, embodiments of the present invention provide an IPA that can trigger on sideband data and capture/filter both protocol data and sideband data as a result. As a result, the user can see the relationship between the captured sideband and the protocol data for debugging purposes. Furthermore, the IPA can also trigger on system events, such as a data mismatch, for example. In yet another embodiment, memory modules that are allocated to particular DUTs during testing can be made available for capture data of other DUTs being tested to expand the depth of capture data available for the other DUTs. In other words, the allocated memory modules of DUTs not being actively tested can be made available to a “data pool” which can be used by other DUTs being actively tested. This technique is referred to herein as “memory pooling.”

Embodiments of the present invention further provide an IPA that can monitor the protocol signals used to communicate with the DUTs internally, within the tester hardware. For example, if FPGAs are used to communicate with the DUTs, the IPA can be implemented directly on the FPGA that is communicating with the DUTs and, thereby, have access to internal protocol signals that a standard protocol analyzer would not have. Because the IPA is implemented directly on the hardware (e.g., FPGAs), there is no need for additional probes and associated signaling that is typically associated with conventional desktop protocol analyzers. Further, the IPA can be implemented on multiple devices (e.g., FPGAs) within the hardware and, accordingly, embodiments of the present invention are able to monitor communication with hundreds of DUTs simultaneously (without requiring a standalone protocol analyzer). It should be noted that the IPA can also be implemented on a different custom ASIC other than an FPGA.

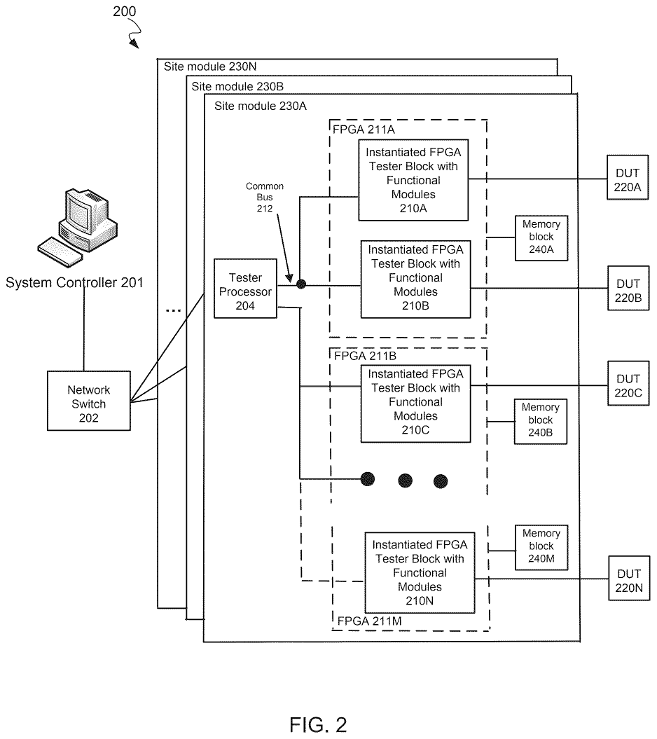

FIG. 2 is an exemplary high level block diagram of the automatic test equipment (ATE) apparatus 200 in which a tester processor is connected to the devices under test (DUTs) through FPGA devices with built-in functional modules in accordance with an embodiment of the present invention. In one embodiment, ATE apparatus 200 may be implemented within any testing system capable of testing multiple DUTs simultaneously.

Referring to FIG. 2, an ATE apparatus 200 for testing semiconductor devices more efficiently in accordance with an embodiment of the present invention includes a system controller 201, a network switch 202 connecting the system controller to the site module boards 230A-230N, FPGA devices 211A-211M comprising instantiated FPGA tester blocks 210A-210N, memory block modules 240A-240M wherein each of the memory blocks is connected to one of the FPGA devices 211A-211M, and the devices under test (DUTs) 220A-220N, wherein each device under test 220A-220N is connected to one of the instantiated FPGA tester blocks 210A-210N. It should be noted that the DUTs 220A-220N can, in one embodiment, be solid state drives (SSDs). The DUTs may communicate to the FPGA instantiated blocks using one or more of several different protocols, including Non-Volatile Memory Express (NVMe), PCIe and UFS. On-board flash memory of FPGA devices 211A-211M can be programmed automatically using software executed by ATE apparatus 200, according to embodiments. The software can be provided on a tangible medium, such as a DVD, or provided by a file sharing service, such as an FTP server, drop box, or other service provider.

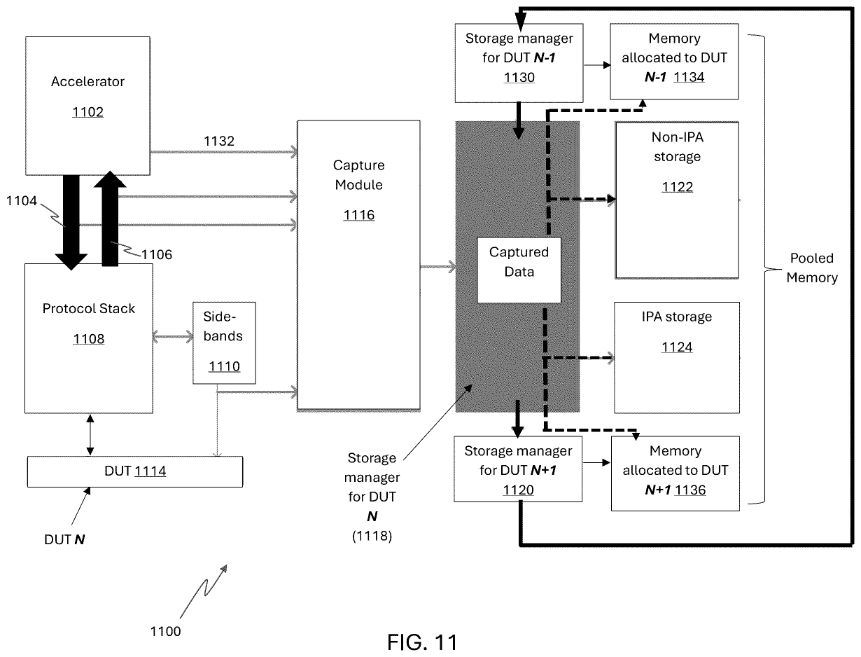

As discussed further below, the memory blocks 240A-240M are allocated, e.g., assigned for use, by particular DUTs 220A-220N being tested. In one embodiment of the present invention, a memory storage manager (FIG. 11), can pool these memory blocks 240A-240M into a pooled memory space. In this way, the pooled memory space is made available for the testing operations (capture data) of any DUT that may need additional capture memory. In other words, via “memory pooling” the memory modules allocated to certain DUTs (e.g., not being tested) can be made available to store capture data pertaining to the testing of other DUTs thereby advantageously increasing the capture depth for those other DUTs to increase testing efficiency.

In one embodiment, the system controller 201 of FIG. 2 may be a computer system, e.g., a personal computer (PC) that provides a user interface for the user of the ATE to load the test programs and run tests for the DUTs connected to the ATE 200. In one embodiment, the system controller 201 may be running the Linux operation system (OS). The Advantest FutureSuite software executing in the Linux environment is one example of test software normally used during device testing. It provides the user with a graphical user interface from which to configure and control the tests. It can also comprise functionality to control the test flow, control the status of the test program, determine which test program is running, and log test results and other data related to test flow. In one embodiment, the system controller can be connected to and control up to thousands of DUTs.

In one embodiment, the system controller 201 can be connected to the site module boards 230A-230N through a network switch, such as an Ethernet switch. In other embodiments, the network switch may be compatible with a different protocol such as TCP/IP, Fibre Channel, 802.11 or ATM, for instance.

In one embodiment, each of the site module boards 230A-230N may be a separate standalone board that attaches to custom-built load board fixtures, on which the DUTs 220A-220N are loaded, and also to the system controller 201 from where the test programs are received. In other embodiments, the site module boards may be implemented as plug-in expansion cards or as daughter boards that plug into the chassis of the system controller 201 directly. Alternatively, the site module boards may be housed within a stand-alone enclosure and may connect to the various DUTs using a device interface board (DIB).

The site module boards 230A-230N can each comprise at least one tester processor 204 and at least one FPGA device. In one embodiment, the tester processor and its associated memory may be located on a separate board (not shown) affixed to the respective site module. This separate board may be called a Computer On Module (or COM) board. In other words, the FPGA may be located on a site module board while the tester processor (with an associated memory) is located on a COM board.

According to other embodiments, the tester processor is a separate rack mounted PC outside of the test head connected to the site module boards 230A-230N by a proprietary serial bus protocol using optical cables. In these embodiments, the tester processor is not affixed to the respective site module.

The tester processor 204 and the FPGA devices 211A-211M on the site module board run the test methods for each test case in accordance with the test program instructions received from the system controller 201. In one embodiment the tester processor can be a commercially available Intel x86 CPU or any other well-known processor. Further, the tester processor may be operating on an x64 Linux-based operating system, such as CentOS x64 or RHEL x64, and running the Core Software, which, for example, allows it to communicate with the software running on the system controller, to run the test methods. In one embodiment, the tester processor 204 may be an x86 processor running the Linux OS or a modified version of the Linux OS. In one embodiment, the Linux OS running on the tester processor is able to receive commands and data from the Windows OS running on the system controller. In alternate embodiments, other operating systems may be running on the tester processor. The tester processor 204 controls the FPGA devices on the site module and the DUTs connected to the site module based on the test program received from the system controller.

The tester processor 204 is connected to and can communicate with the FPGA devices over bus 212. In one embodiment, tester processor 204 communicates with each of the FPGA devices 211A-211M over a separate dedicated bus. In one embodiment, for example in the standard or bypass mode, tester processor 204 can control the testing of the DUTs 220A-220N transparently through the FPGAs with minimal processing functionality allocated to the FPGA devices. In this embodiment, the data traffic capacity of bus 212 can be exhausted rapidly because all the commands and data generated by the tester processor need to be communicated over the bus to the FPGA devices. In other embodiments, the tester processor 204 can share the processing load by allocating functionality to control the testing of the DUTs to the FPGA devices, e.g., in protocol independent data accelerations (PIDA) or full acceleration (FA) modes as will be discussed further below. In these embodiments, the traffic over bus 212 is reduced because the FPGA devices can generate their own commands and data.

In one embodiment, each of the FPGA devices 211A-211M is connected to its own dedicated or allocated memory block 240A-240M. These memory blocks can, among other things, be utilized to store the test pattern data that is written out to the DUTs. In some embodiments, the memory blocks 240A-204M can also store sideband data. In one embodiment, each of the FPGA devices can comprise two instantiated FPGA tester blocks 210A-210B with functional modules for performing functions including implementation of communicative protocol engines and hardware accelerators as described further herein. In other embodiments, each FPGA device may comprise multiple instantiated FPGA tester blocks. Memory blocks 240A-240M can each contain one or more memory modules, wherein each memory module within the memory block can be dedicated to one or more of the instantiated FPGA tester blocks 210A-210B. As described in more detail below, a storage manager can pool the memory of these memory blocks 240A-240M into a pooled memory space and the testing activities (e.g., capture data) of any DUT can be stored in the pooled memory space. This memory pooling increases the capture depth of DUTs being actively tested at the expense of other DUTs not being tested. Accordingly, each of the instantiated FPGA tester blocks 210A-210B can be connected to its own dedicated memory module within memory block 240A. In another embodiment, instantiated FPGA tester blocks 210A and 210B can share one of the memory modules within memory block 240A. In a different embodiment, each FPGA device can have multiple instantiated FPGA tester blocks, each with a respective memory block.

Further, each of the DUTs 220A-220N in the system can be connected to a dedicated instantiated FPGA tester block 210A-210N in a “tester per DUT” configuration, wherein each DUT is assigned its own tester block. This allows separate test execution for each DUT. The hardware resources in such a configuration are designed in a manner to support individual DUTs with minimal hardware sharing. This configuration also allows many DUTs to be tested in parallel, where each DUT can be connected to its own dedicated FPGA tester block and be running a different test program. In a different embodiment, each instantiated FPGA tester block may also be connected to and configured to test multiple DUTs.

The architecture of the embodiment of the present invention depicted in FIG. 2 has several advantages. First, it eliminates the need for protocol-specific hardware bus adapter sockets and cards in the system because the communication protocol modules can be programmed directly on the instantiated FPGA tester blocks within the FPGA devices. The instantiated tester blocks can be configured to communicate with the DUTs in any protocols that the DUTs support, e.g., PCIe, UFS, SATA etc. Accordingly, if DUTs with different protocol support need to be tested, they can be connected to the same system and the FPGAs can be reprogrammed with support for the associated protocols. As a result, one ATE body can be easily configured to test DUTs supporting many different types of protocols.

In one embodiment, new protocols can be downloaded and installed directly on the FPGAs via a simple bit-stream download from a cache on system controller 201 without any kind of hardware interactions. An FPGA will typically include a configurable interface core (or IP core) that is programmable to provide functionality of one or more protocol based interfaces for a DUT and is programmable to interface with the DUT. For example, the FPGAs 211A-211M in the ATE apparatus 200 will include an interface core that can be configured with the PCIe protocol to test PCIe devices initially and subsequently reconfigured via a software download to test UFS-compliant devices. Also, if a new protocol is released, the FPGAs can easily be configured with that protocol via a bit-stream download instead of having to physically switch all the hardware bus adapter cards in the system. Finally, if a non-standard protocol needs to be implemented, the FPGAs can nonetheless be configured to implement such a protocol.

In another embodiment, the FPGAs 211A-211M can be configured to run more than one communicative protocol, wherein these protocols also can be downloaded from system controller 201 and configured through software. In other words, each FPGA implements custom firmware and software images to implement the functionality of one or more PC based testers in a single chip. The required electrical signaling and protocol-based signaling is provided by on-chip IP cores in the FPGAs. As mentioned above, each FPGA is programmable with pre-verified interface or IP cores. This ensures compliance and compatibility according to a given interface standard. The programmable nature of the FPGA is utilized to optimize flexibility, cost, parallelism and ability to upgrade for storage testing applications from SSDs, HDDs and other protocol based storage devices.

For instance, in one embodiment, instantiated FPGA tester block 210A can be configured to run the PCIe protocol while instantiated FPGA tester block 210B can be configured to run the UFS protocol. This allows the tester hardware to test DUTs supporting different protocols simultaneously. FPGA 211A can now be connected to test a DUT that supports both PCIe and UFS protocols. Alternatively, it can be connected to test two different DUTs, one DUT supporting the PCIe protocol and the other DUT supporting the UFS protocol, where each instantiated functional module (e.g., 210A, 210B) is configured with a protocol to test the respective DUT to which it is connected.

In one embodiment, the interface or IP core in the FPGA may be acquired from a third party vendor but may require some customization to be compatible with the embodiments described herein. In one embodiment, the interface core provides two functions: a) wraps storage commands into a standard protocol for transmission over a physical channel; and 2) is the electrical signal generator and receiver.

The other major advantage of the architecture presented in FIG. 2 is that it reduces processing load on the tester processor 204 by distributing the command and test pattern generating functionality to FPGA devices, where each DUT has a dedicated FPGA module running the test program specific to it. For instance, instantiated FPGA tester block 210A is connected to DUT 220A and runs test programs specific to DUT 220A. The hardware resources in such a configuration are designed in a manner to support individual DUTs with minimal hardware sharing. This “tester per DUT” configuration also allows more DUTs to be tested per processor and more DUTs to be tested in parallel. Furthermore, with the FPGAs capable of generating their own commands and test patterns (and sideband data) in certain modes, the bandwidth requirements on bus 212 connecting the tester processor with the other hardware components, including FPGA devices, device power supplies (DPS) and DUTs, is also reduced. As a result, more DUTs can be tested simultaneously than in prior configurations. In other words, without the tester processor 204 acting as a bottleneck, each of the FPGAs can connect to several DUTs and test them concurrently.

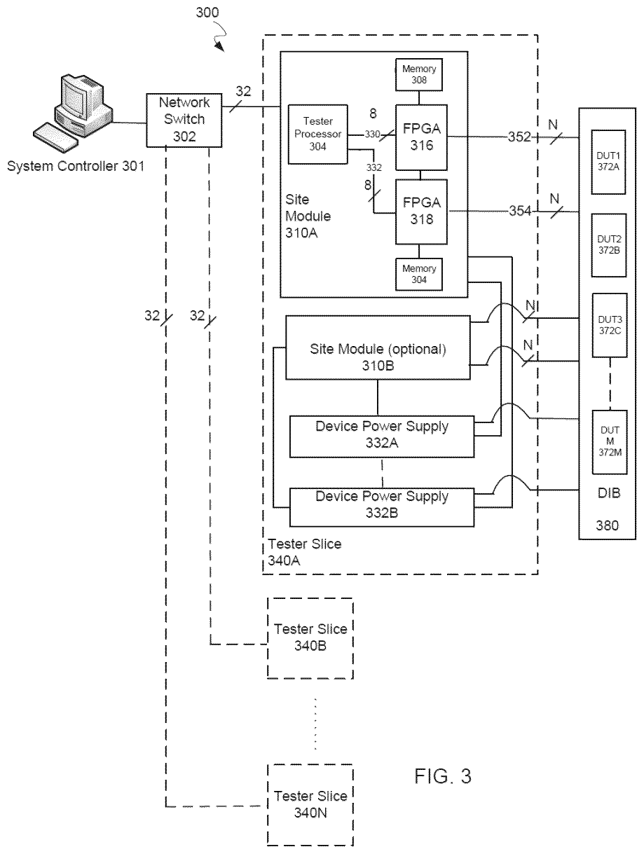

FIG. 3 provides a more detailed schematic block diagram of the site module and its interconnections with the system controller and the DUTs in accordance with an embodiment of the present invention.

Referring to FIG. 3, the site modules of the ATE apparatus, in one embodiment, can be mechanically configured onto tester slices 340A-340N, wherein each tester slice comprises at least one site module. In certain typical embodiments, each tester slice can comprise two site modules and two device power supply boards. In other embodiments, the tester slice may comprise more or fewer site modules and/or power supply boards. Tester slice 340A of FIG. 3, for example, comprises site modules 310A and 310B and device power supply boards 332A and 332B. However, there is no limit to the number of device power supply boards or site modules that can be configured onto a tester slice. Tester slice 340 is connected to system controller 301 through network switch 302. System controller 301 and network switch 302 perform the same function as elements 201 and 202 in FIG. 2 respectively. Network switch 302 can be connected to each of the site modules with a 32 bit wide bus or via ethernet using a serial bus with 1 Tx and 1 Rx differential lane, for example.

As mentioned above, in one embodiment, the system controller 301 may be a computer system, e.g., a personal computer (PC) that provides a user interface for the user of the ATE to load the test programs and run tests for the DUTs connected to the ATE 300. Typically the system controller will run the Linux operating system. The Advantest FutureSuite is one example of test software normally used during device testing.

Each of the device power supply boards 332A-332B can be controlled from any of the site modules 310A-310B. The software running on the tester processor 304 can be configured to assign a device power supply to a particular site module. In one embodiment, the site modules 310A-310B and the device power supplies 332A-332B are configured to communicate with each other using a high speed serial protocol, e.g., Peripheral Component Interconnect Express (PCIe), or other proprietary protocol (e.g., LinkBus).

In one embodiment, each site module is configured with two FPGAs as shown in FIG. 3. Each of the FPGAs 316 and 318 in the embodiment of FIG. 3. is controlled by the tester processor 304 and performs a similar function to FPGAs 211A-211M in FIG. 2. The tester processor 304 can communicate with each of the FPGAs using a 8 lane high speed serial protocol interface such as PCIe as indicated by system buses 330 and 332 in FIG. 3. In other embodiments, the tester processor 304 could also communicate with the FPGAs using different high speed serial protocols, e.g., NVMe, Serial AT Attachment (SATA), etc.

FPGAs 316 and 318 are connected to memory modules 308 and 304 respectively, where the memory modules perform a similar function to memory blocks 240A-240N in FIG. 2. The memory modules are coupled with and can be controlled by both the FPGA devices and the tester processor 304. As discussed in more detail, these memory modules can also be pooled via “memory pooling” so that the entire memory space can be made available to store capture data for any DUT. As depicted in FIG. 3, memory 308 is wired directly to FPGA 316 and memory 304 is wired to FPGA 318. FPGAs 316 and 318 are wired to each other allowing either FPGA to access both memory modules 304 and 308.

FPGAs 316 and 318 can be connected to the DUTs 372A-372M on the DIB 380 through buses 352 and 354 respectively. The DIB 380 is a physical harness that allows a general purpose high speed connection at the site module end that is agnostic to the protocol used to communicate to the DUTs in on lines 352 and 354. At the DUT end, however, the DIB needs to be designed so as to have connectors specific to the protocol being used by the DUT.

The DUTs 372A-372M, in one embodiment of the invention, are loaded on a DIB 380 that is placed outside of a thermal chamber (not pictured) for testing. The DUTs 372A-372M are placed inside the thermal chamber, and the DIB 380 derive power from the device power supplies 332A and 332B. The DUTs may also connect to the FPGAs through a device interface board.

The number of DUTs that can be connected to each FPGA is contingent on the number of transceivers in the FPGA and the number of I/O lanes required by each DUT. In one embodiment, FPGAs 316 and 318 can each comprise 32 high speed transceivers and buses 352 and 354 can each be 32 bits wide, however, more or less can be implemented depending on the application. If each DUT requires 8 I/O lanes, for example, only 4 DUTs can be connected to each FPGA in such a system.

In one embodiment, the communication protocol used to communicate between the tester processor 304 and the DUTs 372A-M can advantageously be reconfigurable. The communicative protocol engine in such an implementation is programmed directly into one or both of the FPGAs on the tester slice. The FPGA (e.g., 316 or 318) can therefore be configured to communicate with the DUTs in any protocol that the DUTs support. This advantageously eliminates the need for swapping out a tester each time a DUT with a different protocol needs to be tested. In one embodiment, the protocols can be high speed serial protocols, including but not limited to UFS, SATA, SAS, NVMe or PCIe, etc. The new or modified protocols can be downloaded and installed directly on the FPGAs via a simple bit-stream download from the system controller through the tester processor without any kind of hardware interactions. Also, if a new protocol is released, the FPGAs can easily be configured with that protocol via a software download.

In one embodiment of the present invention, each FPGA comprises a number of protocol engine modules, wherein each of the protocol engine modules within a FPGA device can be configured with a different communicative protocol.

Accordingly, an FPGA device can be connected to test multiple DUTs, each supporting a different communicative protocol simultaneously. Alternatively, an FPGA device can be connected to a single DUT supporting multiple protocols and test all the modules running on the device simultaneously. For example, if an FPGA is configured to run both PCIe and UFS protocols, it can be connected to test a DUT that supports both PCIe and UFS protocols. Alternatively, it can be connected to test two different DUTs, one DUT supporting the PCIe protocol and the other DUT supporting the UFS protocol.

It should be noted that while the discussion in connection with FIGS. 2 and 3 has focused on FPGAs, the protocols (e.g., UFS, PCIe etc.) can also be implemented on other custom ASICs besides FPGAs.

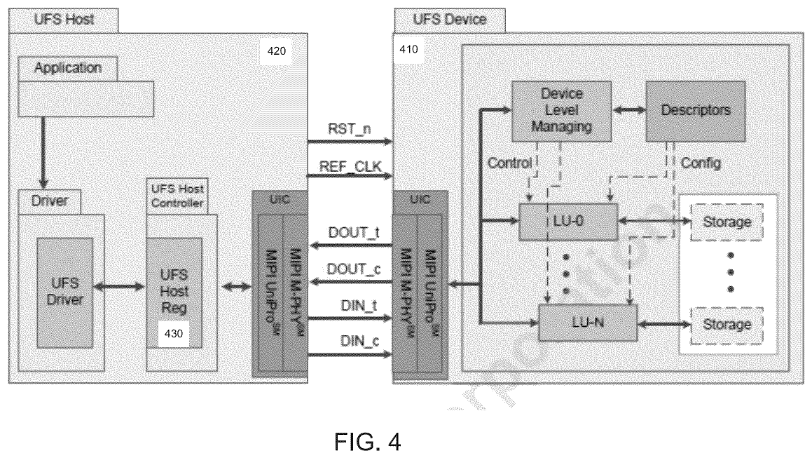

FIG. 4 illustrates a UFS device in communication with a UFS host. As mentioned above, UFS is a high-speed communication protocol between a host controller 420 and a memory device 410. For example, in embodiments of the present invention, FPGAs 316 and 318, the host controllers, would communicate with and control the UFS-compliant DUTs, the memory devices.

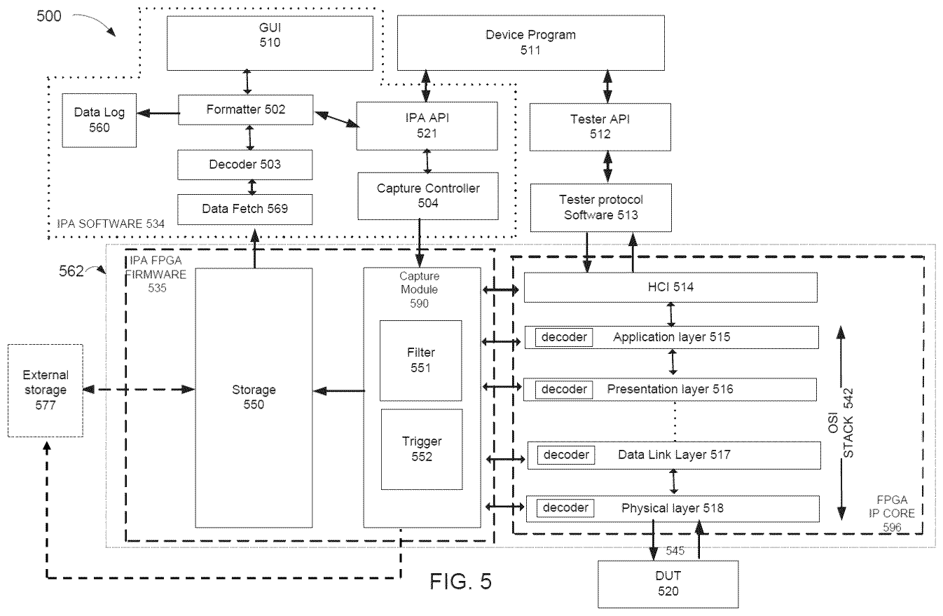

The UFS host 420 comprises an application that wishes to communicate with the UFS device 410. The UFS host will communicate with the device (e.g., a DUT) using the UFS driver. The UFS driver is meant for managing the UFS host controller through the UFS HCI (UFS Host Controller Interface). The UFS HCI is typically a set of registers exposed by the host controller. The HCI is a defined interface between firmware (which implements the protocol stack for the UFS protocol, as will be discussed further in connection with FIG. 5), and application software, which implements sending requests and receiving responses via the HCI. The HCI may be comprised within the UFS Host Register module 430.

### Integrated Protocol Analyzer

As mentioned previously, a drawback of conventional ATE systems relates to the test equipment required to test whether the ATE systems are communicating properly with the DUTs. A traditional protocol analyzer, for example, requires an electrical component, such as a probe, to be inserted into the signal path. With hundreds of DUTs connected to a single ATE, however, there is no practical way to physically insert hundreds of probes into the respective signal paths and the associated cabling would be unmanageable. Also, the cost would be prohibitive. Commercial protocol analyzers are prohibitively expensive and supporting hundreds of such protocol analyzers is simply not feasible in a test environment.

An additional drawback associated with conventional ATE is that they typically only report pass/fail results or other nominal information. In other words, the ATE only reports whether one or more devices under test (DUTs) passed or failed the respective test being executed. In some instances, conventional testers may provide address of failures and the expected versus actual data. However, the ATE is not configured to identify root causes of device failure that occur during qualification testing. Typically, the ATE will not have any hardware or software-based tools built into it that would enable engineers to easily diagnose problems with the DUTs. In a typical testing environment, the engineers operating the ATE will need to identify the cause of failure manually by collecting data logs and performing manual analysis on the logs. This approach is labor intensive, error prone and not scalable.

To address the drawbacks of conventional ATE, embodiments of the present invention provide a tester system with an integrated protocol analyzer (IPA) that is configured into the tester hardware. FIG. 5 illustrates a tester system 500 with an IPA that is configured into the tester hardware in accordance with an embodiment of the present invention.

In the embodiment of FIG. 5, the IPA is configured directly onto a programmable logic device, e.g., FPGA 316 or 318. In other words, the IPA is implemented using the pre-existing hardware of the tester, for example, the FPGA 562. It should be noted that while the IPA in FIG. 5 is illustrated as being implemented on an FPGA, the IPA can be implemented on any one of several types of programmable logic devices. It should be noted that the IPA is not limited to an FPGA and can be implemented on a custom ASIC as well.

In addition to the FPGA firmware component 535, the IPA also comprises a software component 534 that may be implemented, for example, on a system controller, e.g., system controller 301. In other words, the integrated protocol analyzer comprises both an FPGA firmware component 535 and a software component 534, the former being implemented on the FPGA 562 (along with the IP Core 596) while the latter is implemented in software on a server or desktop computer.

As noted above, the FPGA in the tester will typically include a configurable interface core (or IP core) 596 that is programmable to provide functionality of one or more protocol based interfaces for a DUT and is programmable to interface with the DUT. The IP Core 596 is the electrical signal generator and receiver for the signals exchanged over communication link 545. For example, the FPGAs, e.g., FPGAs 211A-211M and FPGAs 316 and 318 in the ATE apparatus will include an IP Core that may be configured with the PCIe protocol to test PCIe devices initially and subsequently reconfigured via a software download to test UFS-compliant devices. The embodiment of FIG. 5, however, illustrates an IP Core 596 that is configured to communicate with DUT 520 using the UFS protocol (the HCI module 514, as will be discussed further below is particular to the UFS protocol). It should be noted though the FPGA 562 can be reconfigured or reprogrammed to support other types of protocols as well. Further, the IPA of the present invention can be used to monitor internal protocol signals of an IP Core 596 regardless of the type of protocol implemented on the IP Core. In other embodiments of the present invention, described further below, the IPA can also monitor sideband data and system events and commands (e.g., within a testing sequence).

The IPA firmware 535 can be implemented directly on an FPGA in addition to the FPGA IP Core 596. Implementing the IPA firmware 535 on the FPGA directly allows the protocol (e.g., PCIe, UFS, etc.) used to communicate with the DUTs to be monitored at or in the IP core 596. There is no need for additional probes and associated cabling. The protocol can be monitored for hundreds of devices simultaneously because the IPA firmware 535 can be implemented on each of the FPGAs, e.g., FPGAs 211A, 211B, etc. in communication with the DUTs. In one embodiment, a respective IPA can be implemented on each of the instantiated FPGA tester blocks, e.g., 210A, 210B, 210C, etc.

A conventional protocol analyzer would typically comprise an interposer that needs to be situated in between the protocol core 596 of the tester and a connected DUT 520. Alternatively, a conventional protocol analyzer or oscilloscope may comprise probes that tap off the signaling wires comprising communication link 545. In both these cases, monitoring communication link 545 by inserting an interposer or probing the line affects the test results from the subtlest to more coarse ways. Programming the protocol analyzer into the tester hardware advantageously avoids corrupting the test results because there is no need to physically probe or alter communication link 545 in any way.

In one embodiment, several features of a standalone protocol analyzer can be built into the software 534 and firmware 535 components of the IPA. For example, the IPA firmware and software can be programmed to collect diagnostic and other protocol related information about the tests. The IPA uses a capture module 590, comprising a trigger module 552 and filter module 551, to selectively capture desired signal information, thereby, reducing the amount of memory needed for data collection. According to embodiments of the present invention, trigger module 552 can trigger on prescribed sideband data and prescribed system events. Triggering on sideband data can result in simultaneous capture/filter of both sideband and protocol data. Likewise, triggering on system events can result in simultaneous capture/filter of both sideband and protocol data.

The IPA firmware and software can be programmed to collect only the critical information relevant to an engineer using capture module 590, selectively discard the less critical information, and store the critical information to the engineer in an organized and timely manner in storage module 550. The storage module 550 may be a memory buffer implemented directly on the IPA FPGA firmware 535, thereby, requiring no additional circuitry for storing the critical information. Alternatively, the critical data may be stored in an external high speed buffer 577. It should be noted that the invention herein is not limited to FPGAs, the capture and storage modules of the present invention can be programmed onto other types of programmable logic devices or custom ASICs as well. According to embodiments described herein, capture module 590 can store both protocol data and sideband data.

The protocol information (and sideband data) can then be reported out to the user through the graphical user interface 510 (GUI) of the software module 534. In one embodiment of the present invention, the GUI 510 may be implemented on a system controller, e.g., system controller 301. The system controller may, for example, be an attached server or desktop computer. The desktop computer may be executing the GUI and other programs that allow the user to examine the protocol information using the GUI. The GUI and other application programs may also allow user-created scripting so that the user can direct the program to search the serial or protocol data for anomalies and root causes of errors.

As noted above, conventional ATE is not configured to identify root causes of device failure that occur during qualification testing. In a typical testing environment, the engineers operating the ATE will need to identify the cause of failure manually by collecting data logs and performing manual analysis on the logs. Embodiments of the present invention build in scripting tools into the IPA software 534 that will parse through the data captured by the IPA firmware 535 and advantageously determine root causes of device failures by searching for anomalies in the log files (which may be preserved in data log module 560).

Embodiments of the present invention are also able to monitor the protocol signals (generated in connection with the protocol used to communicate with the DUT) internally, within the tester hardware. For example, if FPGAs are used to communicate with the DUTs, the IPA can be implemented directly on the FPGA that is communicating with the DUTs and, thereby, have access to internal protocol signals that a standard protocol analyzer would not have. Because the IPA is implemented directly on the hardware (e.g., FPGAs), there is no need for additional probes and associated signaling that is typically associated with conventional desktop protocol analyzers.

Integrating the IPA firmware module 535 with the FPGA IP Core module 596 on each FPGA allows the protocol analyzer capabilities to be made available for each FPGA connected with a DUT without the need for any additional probing or cabling. The IPA can be implemented on multiple FPGA devices within the hardware and, accordingly, embodiments of the present invention are able to monitor communication with hundreds of DUTs simultaneously (without requiring a standalone protocol analyzer). This also results in a substantial reduction in costs the only cost of implementing the IPA firmware 535 is consumption of additional gate capacity in the FPGA. However, with the high gate counts of typical off-the-shelf FPGAs, this is an insignificant cost.

As noted previously, in the embodiment illustrated in FIG. 5, the IP Core 596 implements the UFS protocol. The UFS HCI module 514 is typically a set of registers exposed by the FPGA host controller. The HCI is a defined interface between the FPGA firmware (comprised, among other things, of the IPA FPGA firmware block 535 and the FPGA IP Core block 596), and application software 513, which implements sending requests and receiving responses via the HCI. The FPGA IP Core 596 receives the test or device program 511 through the tester API 512. The device program may, for example, execute on the system controller 301 and can be used to program the tester (including the FPGA 562) through the tester API 512. The test protocol software 513 communicates with the HCI module 514 in firmware and conveys protocol information from the OSI stack 542 back to the system controller using tester API 512.

In one embodiment, the IP Core 596 implements the OSI protocol stack 542. As is well known, the OSI protocol stack 542 comprises at least 7 layers, including an application layer 515, a presentation layer 516, a data link layer 517 and a physical layer 518. UFS communication is a layered communication architecture. The electrical interface for UFS uses the physical layer 518 comprising the board components, PCB channel, and actual voltage signals for link 545 that are communicated with the connected DUT 520.

In a conventional tester system, the physical signals of the communication link 545 would need to be probed by a standalone instrument. Further, the standalone protocol analyzer would only have access to the external signals of the communication link 545 and would need to reconstruct the internal state of the firmware (including any internal signals within the IP Core 596, e.g., signals communicated between the various layers in the OSI stack 542) using the external signals of link 545.

Implementing the IPA in firmware (using the firmware module 535) and in software (using the software module 534), enables signals that are internal to the IP Core 596 to become visible and available for inspection internally using the FPGA firmware 535. Using capture module 590 and storage buffer 550 (or external storage 577) allows the tester to advantageously collect information pertaining to device failure from modules and buffers inside the tester firmware itself. As a result the IPA of the present invention provides better tracing information leading up to and following failures plus the ability to further debug beyond just what was easily measured as a pass or fail address/data location. In some instances, data from capture module 590 is sent directly to external storage 577 bypassing internal storage 550.

For example, as shown in FIG. 5, the capture module 590 would have access to signals at each level of the protocol stack 596. The capture module may be able to access and monitor signals from the HCI interface 514. The HCI interface provides access to the FPGA firmware and to modules within the firmware that keep track of and hold the internal states of the firmware. The IPA of the present invention is able to provide access to these internal states of the firmware that a traditional protocol analyzer simply would not be able to access. Additionally, in some embodiments, some of the signal analysis can be performed post-capture by IPA Software 534 or via GUI 510.

Further, the capture module 590 may be able to monitor signals being transmitted to or from one of the protocol layers (e.g., application layer 515, presentation layer 516). In other words, the capture module may be configured to tap into signals internal to each of the protocol layers. The capture module may further be able to monitor transactions between the various protocol layers. Unlike a traditional protocol analyzer, the IPA firmware 535 would have direct access to the intermediate protocol signals from the OSI stack implemented in the IP core 596, and would not need to reconstruct the information using only the signals of the link 545 at the level of the DUT interface.

In one embodiment, a capture module 590 can comprise a traffic-filtering module 551. A filtering module 551 selectively reduces the amount of traffic that the capture module will collect. Because buffer space inside the FPGA is limited, a filtering module may be used within the capture module 590 to filter or selectively choose a subset of the packets that would be of most interest to the user for diagnostic purposes.

In one embodiment, the acquisition logic of the filtering module 551 of the capture block selects and captures the information regarding the data traffic, states or status of various signals and transfers the information to the storage block 550 so it can be saved. The acquisition logic of the filtering module 551 can also selectively capture the desired data. In other words, the acquisition logic may be programmed to gather only a subset of data inputted into the capture block. Certain configuration bits can be programmed into the filtering logic that specify how much of the incoming data should be captured, e.g., in certain instances only the headers of the incoming packets may need to be captured.

In one embodiment, the filtering module 551 of the capture module may only capture certain types of data, e.g., data packets with a particular bit configuration and/or prescribed sideband data. The filtering module can also be programmed to selectively capture only the desired data packets while ignoring the rest. The filtering module can also be programmed to selectively capture only the desired sideband data while ignoring the rest.

In one embodiment, the capture module 590 can comprise a trigger module 552. The trigger module 552 comprises FPGA logic that stops a capture based upon a detected event. In other words, if a user wanted to stop capturing traffic after detecting a particular condition, the trigger module can be programmed to detect the condition. In one embodiment, the trigger module 552 may trigger to start once an event is detected, for instance, capture data once it detects a particular type of pattern in the incoming data. In other words, the trigger module 552 may be configured to pattern match data until it detects a match and, subsequently, capture any incoming data. According to other embodiments described herein, the trigger module 552 can trigger on prescribed sideband data and can trigger based on the detection of certain system events and test sequence commands.

In one embodiment, the triggering module 552 may have the additional capability of compressing data received from the IP Core 596 by identifying identical sequences that repeat. For example, in certain communication protocols, identical training sequences are sent repeatedly, sometimes in the thousands. The triggering module 552 can, in one embodiment, collect the first one and keep track of the number of times the identical sequence was transmitted (or received) from, for example, the DUT 520. In one embodiment, this functionality is provided by a combination of trigger module 552 and filtering module 551. For example, the trigger module 552 may find and save the first of the repeated patterns or packets. The filtering module 551 may then remove and count the redundant patterns. Compression is disabled when there is simultaneous data transmitted in both directions (Tx and Rx) to preserve the timing sequence of events in both directions.

By comparison, conventional protocol analyzers collect all the sequences and optionally perform the compression when displaying the sequences to the user. The IPA, on the other hand, will advantageously only report out the first collected sequence and indicate the number of times it was transmitted. In one embodiment, this report may be presented to the user through GUI 510. It should be noted that the memory 550 for the IPA of the present invention can be significantly less than a memory required for a conventional protocol analyzer because the IPA of the present invention will only save critical information that needs to be reported out to the user and discard the less critical information.

In one embodiment, the trigger module 552 may be configured to recognize certain pre-determined decoded patterns in each of the layers of the OSI stack 542. As shown in FIG. 5, each layer of the OSI stack comprises a decoder that decodes signals from the respective layer. The trigger module can trigger on any decoded patterns from each layer of the OSI stack. In other words, the trigger module 552 is able to tap into the protocol signals being exchanged between the layer and trigger on any event, condition or pattern that appears on the signals.

In one embodiment, the trigger module 552 may also be configured to perform selective discard. For example, in certain protocols, e.g., PCIe, repeated training sequences need to be transmitted that do not need to be reported to the user. The trigger module 552 can monitor and discard those training patterns. Further, the IPA may create and report out only if the pattern appears to fall outside of specification mandates. In other words, the trigger module 552 may be programmed to check patterns to determine if they were out of specification mandates - in such a case, a report would be created for the user through GUI 510.

The decoder within each of the application layers within the IP Core 596 decodes signals within a respective layer to provide attributes that are stored at each layer. Each layer will typically comprise its own attributes as a result of the decoding. In one embodiment, the IPA is capable of performing triggering and filtering in the capture module 590 using the attributes associated with each of the respective application layers.

By comparison, a standalone protocol analyzer would not typically have exposure to the intermediate decoded signals communicated between layers. The standalone protocol analyzer would instead need to decode physical signals comprising link 545 in order to derive or extract any internal states or signals within the OSI stack 542.

It should be noted that in some embodiments, the functionality of the trigger module 552 and filter module 551 might be split between the capture module 590 and storage module 550. In other words, the storage module 550 may perform some of the triggering and filtering features explained above.

In one embodiment, the capture module 590 may be configured using a capture controller module 504 on the tester. The device program 511 through the IPA API 521 accesses the capture controller module 504 on the tester. The IPA API may be an interface executing, for example, on the system controller along with the device program 511. The device program 511, designed by the user, will typically control the types of triggers and filters set up on the capture module 590. The device program 511 accesses the capture module 590 and configures the triggering and filtering conditions using capture controller module 504. As mentioned earlier, the device program 511 also controls the manner in which the firmware will be programmed, e.g., through the HCI interface 514.

In one embodiment, the data accumulated by the capture module 590 is stored in the storage module 550 (also implemented on the FPGA 562) or, alternatively, on external storage module 577. The captured data is accessed by a data fetch module 569, decoded by a decoder 503, and formatted using a formatter module 502. The data can be logged on a data log module 560. The critical data, including the information that is of most interest to the tester, may be selected and displayed through the GUI 510.

In one embodiment, the data fetch module 569 links the IPA software 534 to the IPA firmware 535. The data fetch module may retrieve the data from storage module 550 and store it in a way so that it may be easily accessed by the software components. In one embodiment, the data decoder may decode the data from the data fetch module and interpret it to identify error and other conditions of interest to the user. In one embodiment, some of the data analysis capabilities including user-prepared scripts to parse through the test data may be built into the decoder module 503.

In one embodiment, the protocol traffic (including sideband data) captured from the capture module of the IPA can be transmitted to software 534 and converted into a graphical illustration. Most conventional protocol analyzers display the data in a graphical format. Accordingly, embodiments of the present invention facilitate analysis by graphically displaying the data captured. The graphical interface is usually easier to interpret and use because the data has been sorted and labeled to highlight key features of the communication that would otherwise need to be manually teased out of the raw textual data by referring to the protocol specification. Accordingly, software 534 can perform further post-processing of the data gathered from the capture module in order for the user to be able to view the data in a graphical manner using GUI 510.

In one embodiment, the capture module may be programmed with the necessary logic to identify and flag any error condition that may occur during any stage of the communication between the protocol stacks. The capture module may be further programmed to determine if the error resulted from the DUT or resulted from a problem in the protocol stacks within IP Core 596. For example, if an error condition is detected in the data received from any of the signals or states under investigation in the protocol stacks, the capture module may comprise the necessary logic to identify and flag the error condition. The error condition information may then be transferred to the storage module 550 and subsequently to the GUI 510.

In one embodiment, capture module 590 may be programmed to analyze the data received from a connected DUT, e.g., DUT 520, and identify a device failure precursor. In other words, capture module 590 may use the data gathered from the DUT to indicate that the DUT will fail imminently. Capture module 590 may then flag an error condition or a potential error condition and relay information pertaining to the error to GUI 510 so the user can be alerted. In other embodiments, capture module 590 may be programmed to analyze sideband data received from a connected DUT.

In one embodiment, capture module 590 may also contain logic circuitry and be programmed to analyze the information captured and to identify a cause of error. For example, the capture module may be programmed with a rule checker that is run on the information collected. In other words, the rule-checker can parse through all the failure related information captured to identify some possible causes of the failure by running a set of rules on the information captured. In other embodiments, capture module 590 may be programmed to analyze system events that occur during testing, such as data mismatches.

In one embodiment, the capture module logic may vary depending on the protocol implemented by the IP Core 596. For example, capture module logic for interfacing with an IP Core 596 implementing the PCIe protocol may be different from capture module logic for interfacing with an IP Core running the UFS protocol of FIG. 5.

In one embodiment, a capture module may comprise logic that logs activity detection events. If there is any activity detected on certain designated lines within the IP Core 596, the capture module will log such events to present to the user.

In one embodiment, a capture module 590 can comprise data logging capture capabilities. The capture module comprises FPGA logic that compares the expected versus received data and displays the results to the user by sending them to software block 534 where the GUI 510 displays the results to the user.

In one embodiment, a timestamp is associated with each entry when it is saved in the storage module 550. This allows the data to be sorted easily. This is especially convenient after data from the capture module in the FPGA has been transferred to the software module 534. The time-stamped data can be sorted using the time-stamps, which makes it advantageous for an engineer to quickly view and interpret the results in time-order and diagnose any problems. In addition to the data and the time-stamp, in some cases metadata may also be stored with the entries from the capture module 590 containing additional details regarding the event. For example, if the capture module stores information pertaining to state change events, then metadata regarding the type of state change event may be saved with each entry in the storage module 550.

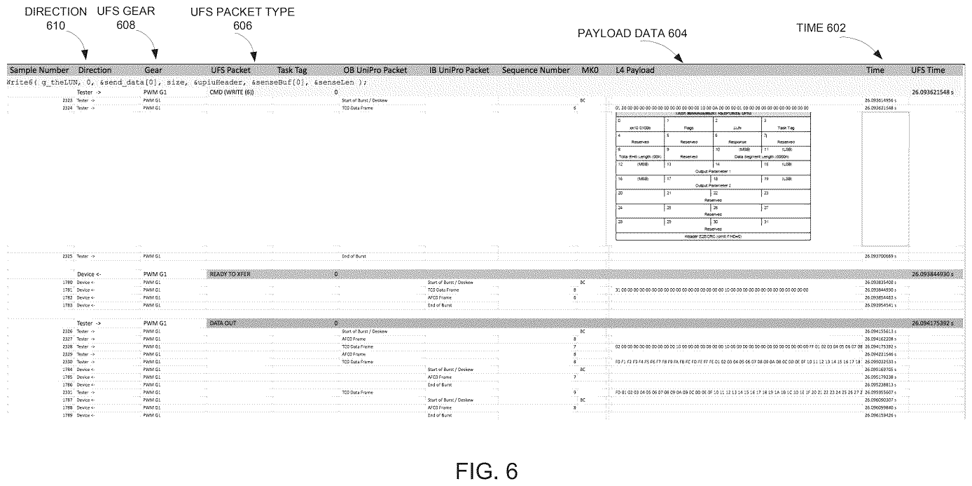

FIG. 6 illustrates an exemplary on screen output that would be displayed through the GUI to a user or printed in accordance with an embodiment of the present invention. As discussed in connection with FIG. 5, the GUI 510 displays protocol details regarding the testing of DUT 520. For example, the user interface provides details regarding the direction 610 of the test—whether the data is being transmitted from the FPGA 562 to DUT 520 or received from the DUT 520.

The interface may also have details regarding the speed at which communication is taking place. For example, if the protocol of choice is UFS, the interface may provide details regarding the UFS gear 608 being used for the communication. As is well known, the UFS protocol communicates using both high speed gears and low speed gears.

The interface may also comprise details regarding the UFS packet type 606, e.g., a write or read packet. Additionally, the interface may comprise details regarding payload data 604, e.g., the data communicated to and from the DUT. Further, the interface may comprise timestamps 602, which report the timestamp on each packet of payload data. The interface may also comprise details regarding captured sideband data and/or the relationship between captured protocol data and sideband data.

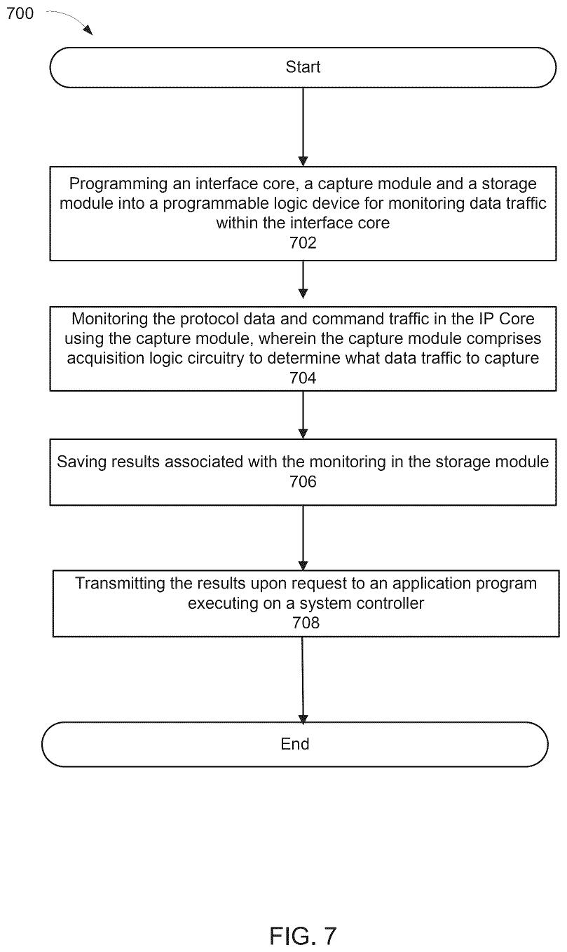

FIG. 7 illustrates a flowchart of an exemplary computer implemented process 700 for monitoring protocol data and command traffic during automated device testing in accordance with one embodiment of the present invention.

At step 702, an interface core (or IP core), a capture module, and a storage module are implemented on a programmable logic device, e.g., an FPGA. The IP Core 596 wraps commands into a standard protocol (e.g., UFS) for transmission over a physical channel. The IP Core 596 also generates and receives electrical signals for transmitting over the physical channel. The capture module 590 is configured to capture protocol related traffic from the IP Core while the storage module 550 is configured to store the data captured by the capture module 590.

At step 704, the protocol data and command traffic in the IP Core 596 is monitored using the capture module. In accordance with other embodiments of the present invention, step 704 also monitors sideband data and system events. In one embodiment, the capture module 590 comprises a triggering module 552 and a filtering module 551. Among other functions, the filtering module filters out particular types or subsets of data or packets of data including sideband data and system events. Further, the trigger module, among other things, triggers on certain patterns of data or certain events in the data to perform actions based on recognizing the respective patterns or events. According to other embodiments, the trigger module, triggers on certain sideband data to perform actions based on recognizing the sideband data.

At step 706, the results associated with the monitoring activities are saved in the storage module 550 that is also implemented on the programmable logic device. As described in more detail below, the results associated with the monitoring activities may include sideband data and may be stored using “memory pooling” techniques with expand the depth of capture data that can be made available to certain DUTs undergoing active testing. Steps 704 and 706 can be performed concurrently, according to embodiments.

Finally, at step 708, the results are transmitted to the tester software application program executing on the system controller. In one embodiment, the results may be decoded and formatted for storage in a file on a local or remote file system, and the file contents can be displayed to a user through a GUI, e.g., GUI 510.

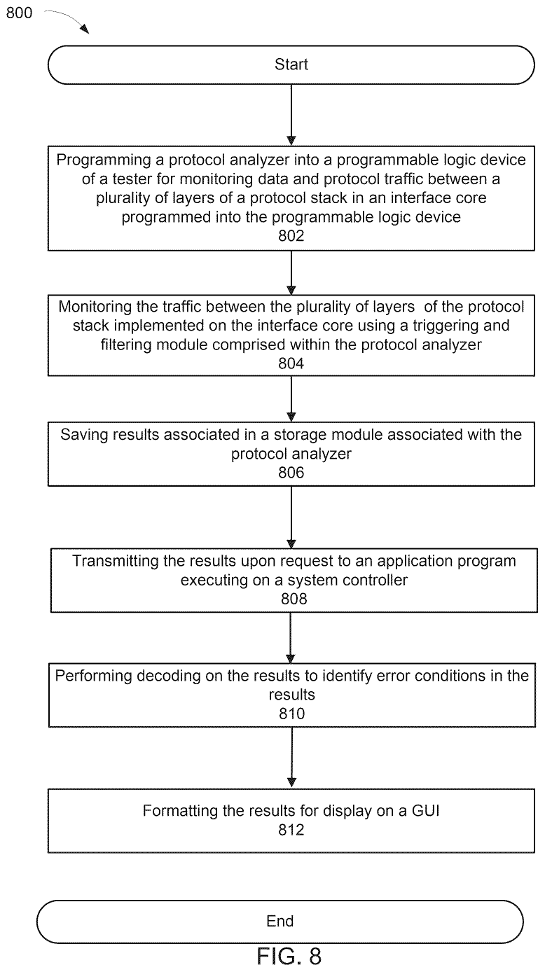

FIG. 8 illustrates a flowchart of an exemplary computer implemented process 800 for programming an integrated protocol analyzer in a tester to collect and display information in accordance with one embodiment of the present invention.

At step 802, an IPA is programmed into a programmable logic device, e.g., an FPGA, to monitor data and protocol traffic between the various layers of the protocol stack of the IP Core 596. More specifically, the IPA can monitor the signals transmitted between the various protocol layers of the IP Core 596. The IPA may also monitor signals communicated between a DUT 520 and the IP Core 596. The FPGA, e.g., FPGA 562, may be connected to one or more DUTs, e.g., DUT 520, to be tested. Further, the FPGA is also connected to a system controller, e.g., system controller 301 that executes the tester software application program and/or the device program for coordinating the tests. At step 802, the IPA may also monitor sideband data.

At step 804, the data traffic between the various layers of the protocol stack implemented on the IP Core 596 and between the DUT 520 and the IP Core 596 are monitored using the protocol analyzer. The protocol analyzer may comprise a filtering module and a triggering module. As mentioned previously, the filtering module filters out particular types or subsets of data or packets of data. Further, the trigger module, among other things, triggers on certain patterns of data or certain events in the data to perform actions based on recognizing the respective patterns or events. At step 804, the triggering module may trigger on sideband data and may also trigger on system events (such as a data mismatch). One of the functions of the filtering and triggering would be to compress the data by selectively filtering out unwanted data or by triggering on sequences that are repeated and choosing only to keep a record of a single repeated sequence (while discarding the others).

At step 806, the results associated with the monitoring are saved in a storage module 550 programmed into the IPA. According to embodiments of the present invention, the results may include simultaneously captured protocol data and sideband data. Steps 804 and 806 can be performed concurrently, according to embodiments.

Subsequently, at step 808, the results are transmitted to the software application program associated with the IPA 534 executing on the system controller. The results can also be stored in a file on local or remote file system, according to embodiments.

At step 810, decoding is performed by decoder module 503 to identify error conditions in the results.

Finally, at step 812, the results are formatted by formatter module 502 to prepare them for display in the GUI 510.

### Sideband and System Event Activity Monitoring and Triggering by an Integrated Protocol Analyzer Having Memory Pooling Capabilities

In one embodiment, the sideband data is captured by the capture module during testing alongside the protocol data, and the captured data can be filtered by the filter module to eliminate unwanted information to preserve memory resources. In another embodiment, various triggers are activated based on tester activity (e.g., system events), and these triggers can be activated at a specific step of a test sequence. In another embodiment, as discussed above, the IPA can pool memory resources allocated to various DUTs (e.g., DUTs that are not being tested or debugged), and the pooled memory resources can be made available to other DUTs that are under active testing, for example, to increase the amount of data that can be captured and stored by the FPGA during testing.

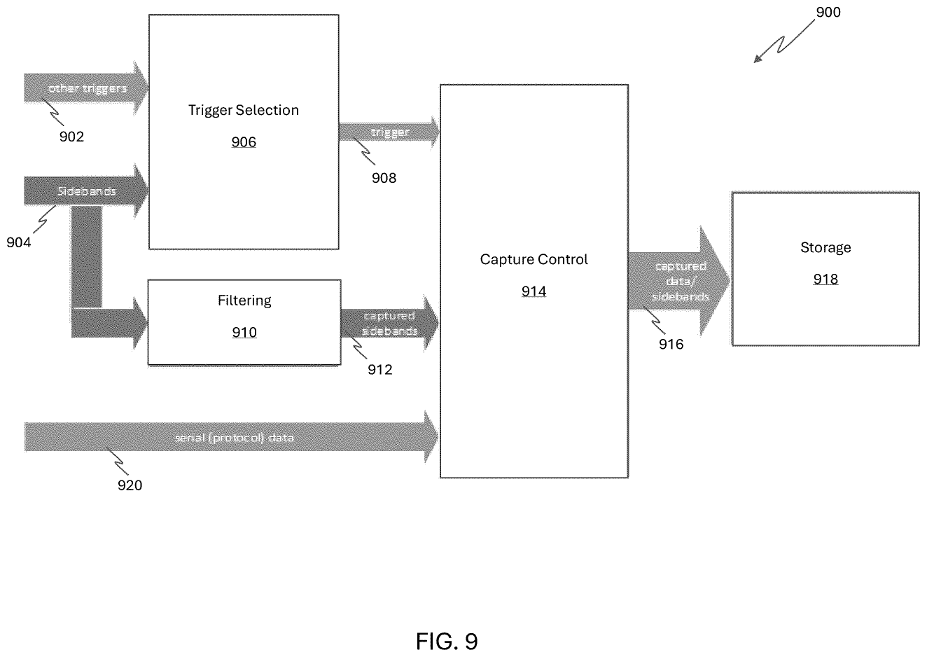

As described in more detail below with respect to FIGS. 9-13, some embodiments of the present invention are drawn to an ATE apparatus in which a tester processor is connected to the DUTs through FPGA devices with built-in functional modules. The ATE apparatus may be implemented within any testing system capable of testing multiple DUTs simultaneously. As described below, one of the functional modules implemented by an FPGA is an integrated protocol analyzer, and the ATE can further include a system controller, a network switch connecting the system controller to site module boards, FPGA devices comprising instantiated FPGA tester blocks, memory block modules, where each of the memory blocks is connected to one of the FPGA devices, and the devices under test, wherein each device under test is connected to one of the instantiated FPGA tester blocks. As described further below, the memory blocks can be pooled together using a technique of “memory pooling”to provide greater capture depth for certain DUTs in active testing.

It should be noted that the DUTs can, in one embodiment, be solid state drives (SSDs). The DUTs may communicate to the FPGA instantiated blocks using one or more of several different protocols, including Non-Volatile Memory Express (NVMe), PCIe and UFS. In one embodiment, the system controller may be a computer system, e.g., a personal computer (PC) that provides a user interface for the user of the ATE to load the test programs and run tests for the DUTs connected to the ATE. In one embodiment, the system controller may be running a Linux-based operation system (OS).

According to some embodiments, the IPA is included in the tester system as a hardware component within an FPGA of the tester, and the IPA is configured into the tester hardware. In other words, the protocol analyzer uses the pre-existing hardware of the tester to collect diagnostic information about the tests, including, for example, sideband communications and protocol data. Further, the IPA uses triggering and filtering techniques to reduce the amount of memory required for collection. Importantly, the IPA of the present invention can collect critical information relevant to an engineer, selectively discard the less critical information, and report the critical information to the engineer in an organized and timely manner.

Embodiments of the present invention further provide an IPA that can monitor the protocol signals and sideband data used to communicate with the DUTs internally, within the tester hardware. For example, if FPGAs are used to communicate with the DUTs, the IPA can be implemented directly on the FPGA that is communicating with the DUTs and, thereby, have access to internal protocol signals that a standard protocol analyzer would not have and also monitor sideband channels. Because the IPA is implemented directly on the hardware (e.g., FPGAs), there is no need for additional probes and associated signaling that is typically associated with conventional desktop protocol analyzers. Further, the IPA can be implemented on multiple devices (e.g., FPGAs) within the hardware and, accordingly, embodiments of the present invention are able to monitor communication with hundreds of DUTs simultaneously (without requiring a standalone protocol analyzer). It should be noted that the IPA can also be implemented on a different custom ASIC other than an FPGA.

The invention includes the tester system with an IPA that is configured into the tester hardware in accordance with an embodiment of the present invention. The IPA is configured directly onto a programmable logic device, e.g., an FPGA. In other words, the IPA is implemented using the pre-existing hardware of the tester, for example, the FPGA. It should be noted that while the IPA is implemented on an FPGA, the IPA can be implemented on any one of several types of programmable logic devices. It should be noted that the IPA is not limited to an FPGA and can be implemented on a custom ASIC as well.

In addition to the FPGA firmware component, the IPA can also include a software component that may be implemented, for example, on a system controller (e.g., system controller 201 depicted in FIG. 2). In other words, according to some embodiments, the integrated protocol analyzer comprises both an FPGA firmware component and a software component, the former being implemented on the FPGA (along with the IP Core) while the latter is implemented in software on an embedded processor, server, or desktop computer, or the like. For example, with reference to FIG. 5, the IPA software component can be implemented as IPA software 534, and the IPA hardware component can be implemented as IPA FPGA firmware 535, which includes storage module 550, and capture module 590, which includes filter module 551 and trigger module 552, although other implementations can be used.

In one embodiment, several features of a standalone protocol analyzer can be built into the software and firmware components of the IPA. For example, the IPA firmware and software can be programmed to collect diagnostic and other protocol related information about the tests from the sideband channel or from the protocol data. The IPA uses a capture module, comprising a trigger module and filter module, to selectively capture desired signal information, thereby reducing the amount of memory needed for data collection. Triggering may be done on protocol data and/or sideband data. The IPA firmware and software can be programmed to collect only the critical information relevant to an engineer using capture module, selectively discard the less critical information, and store the critical information to the engineer in an organized and timely manner in storage module. The storage module may be a memory buffer implemented directly on the IPA FPGA firmware, thereby requiring no additional circuitry for storing the critical information. Alternatively, the critical information may be stored in an external high-speed buffer. It should be noted that the invention herein is not limited to FPGAs, the capture and storage modules of the present invention can be programmed onto other types of programmable logic devices or custom ASICs as well.

In one embodiment, the capture module can comprise the trigger module. The trigger module comprises FPGA logic that starts and/or stops a capture of sideband and protocol data based upon a detected event. In other words, if a user wanted to stop capturing traffic after detecting a particular condition, the trigger module can be programmed to detect the condition. In one embodiment, the trigger module may trigger to start once an event is detected, for instance, to capture data once it detects a particular type of pattern in the incoming data. In other words, the trigger module may be configured to pattern match data until it detects a match and, subsequently, capture any incoming data. Advantageously, the capture mode can store simultaneously captured protocol data and sideband data in response to a trigger event.

In one embodiment, the triggering module may have the additional capability of compressing data received from the IP Core by identifying identical sequences that repeat. For example, in certain communication protocols, identical training sequences are sent repeatedly, sometimes in the thousands. The triggering module can, in one embodiment, collect the first one and keep track of the number of times the identical sequence was transmitted (or received) from, for example, the DUT. In one embodiment, this functionality is provided by a combination of trigger module and filtering module. For example, the trigger module may find and save the first of the repeated patterns or packets. The filtering module may then remove and count the redundant patterns. Moreover, the IPA, can be configured to only report out the first collected sequence and indicate the number of times it was transmitted. In one embodiment, this report may be presented to the user through GUI. It should be noted that the memory for the IPA of the present invention can be significantly less than a memory required for a conventional protocol analyzer because the IPA of the present invention will only save critical information that needs to be reported out to the user and discard the less critical information.

### Sideband Activity Monitoring, Capturing and Filtering by an Integrated Protocol Analyzer

Embodiments of the present invention provide a test system that includes an IPA implemented on an FPGA or other application specific integrated circuit (ASIC) with one or more sideband communication channels. The sideband channels can be used to transmit commands and signals generated by the FPGA (e.g., by a sideband automatic pattern generator (APG) of the FPGA) in communication with a DUT.

Sideband communication channels can be separate from the protocol data channels, and are used to communicate additional information during testing in parallel with the protocol data. In other words, while protocol data (test data) is typically transmitted between test system components and DUTs during testing, a secondary channel (sideband channel) can be used concurrently to communicate other information, without interrupting the typical test activities being performed on the primary channel. Sideband channels are typically used to communicate relatively slow speed commands and signals such as reset signals, clock enable signals, low power mode commands, configuration commands and signals, wake signals free running clock reset signals, etc., from an FPGA or other test system component to a DUT. In some cases, sideband signals may be generated by the DUT and transmitted to the test system.

The sideband channel can be monitored continuously to identify signals, commands, or other data that triggers a certain response by the FPGA or other test system components (e.g., the capturing and/or filtering of data) during device testing. The sidebands are typically implemented using dedicated input/output pins of the DUT and the FPGA over a wired connection. The FPGA can be an instantiated tester block such as instantiated FGPA tester block 210A depicted in FIG. 2, for example.

FIG. 9 is a block and data flow diagram illustrating an exemplary test subsystem that includes an IPA implemented on an FPGA of the test system and configured to capture and trigger based on prescribed sideband data and protocol data in accordance with one embodiment of the present invention. The sideband data typically includes relatively slow-speed signals (typically less than 1 GHz) such as reset signals, clock enable signals, low power mode commands, configuration commands, wake signals, and clock reset commands, for example, which can be transmitted from the FPGA to the DUT to configure or operate the DUT for testing. It should be noted that some sideband signals, such as clock enable signals, can be generated by the DUT and transmitted to the FPGA.

In one embodiment, capture control 914 is configured to capture all filtered sideband activity from sideband channel 904 provided to capture control module 914 as output from the filter module 910 as captured sidebands 912. In this embodiment, captured sidebands 912 includes all sideband data and filtering is optionally performed by filtering module 910 based on user supplied information. The captured data/sidebands 916 are provided by capture control module 914 to storage module 918 for storage, and the sideband data 916 can later be analyzed for debugging purposes, for example.

The capturing of sideband data can be initiated by trigger 908 provided by trigger selection module 906 based on prescribed trigger information. Trigger selection module 906 can be activated by a specific or prescribed sideband signal (e.g., a rising or falling edge), a specific sideband command or command sequence, or a data mismatch indicated by the test system (e.g., a mismatch between expected data generated by a pattern generator and data actually received by the test system) that activates capture control 914 so that data is captured and stored in storage module 918. Alternatively, trigger selection 906 can be configured to provide a trigger 908 to capture control module 914 based on other triggers 902, such as protocol data or system events generated during DUT testing. Moreover, protocol data 920 generated during DUT testing can also be provided to capture control 914, along with any captured sideband data 912, and the captured data 916 can be stored in storage module 918. By capturing both protocol and sideband data simultaneously from a trigger event (sideband and protocol data can also be used for triggering), the user can see the relationship between the sideband and the protocol data for debugging.

Importantly, to save system resources, filtering module 910 can filter incoming sideband data 904 before the captured data 912 is provided to capture control module 914, according to one embodiment. For example, filtering module 910 can be configured to capture only desired sideband signal information in order to save memory resources of storage module 918. In some embodiments, the IPA firmware and software are programmed so that the filtering module 910 only passes critical information to capture control 914, and less important information is filtered out to save resources. A test engineer can specify what types of data are considered critical prior to or during testing. The critical data can then be stored in an external high-speed buffer 918, for example, and the non-critical data can be filtered out. The filtering module 910 can also be configured to detect repeated signals, patterns, or packets, and/or to provide a count of the number of times a specific signal, pattern, or packet has been detected. The repeated signals, patterns, or packets may also be removed by filtering module 910 advantageously to conserve system resources. Although not shown in FIG. 9, the captured protocol data can be filtered before storage, or filtered after storage by the IPA software or manually via a graphical user interface.

### Triggers for Capture Control Based on Test Activity

According to some embodiments, a trigger module can be triggered based on tester activity (e.g., system events and commands) rather than simply taken from protocol or sideband data. For instance, a tester-generated error condition such as a mismatch between the protocol data received and that expected can cause a trigger to be activated. Moreover, if the test system is executing a sequence of test operations (e.g., a test sequence command or system event), the trigger module can be configured to issue a trigger at a specific place or issued command in that sequence (e.g., as defined by a test engineer).

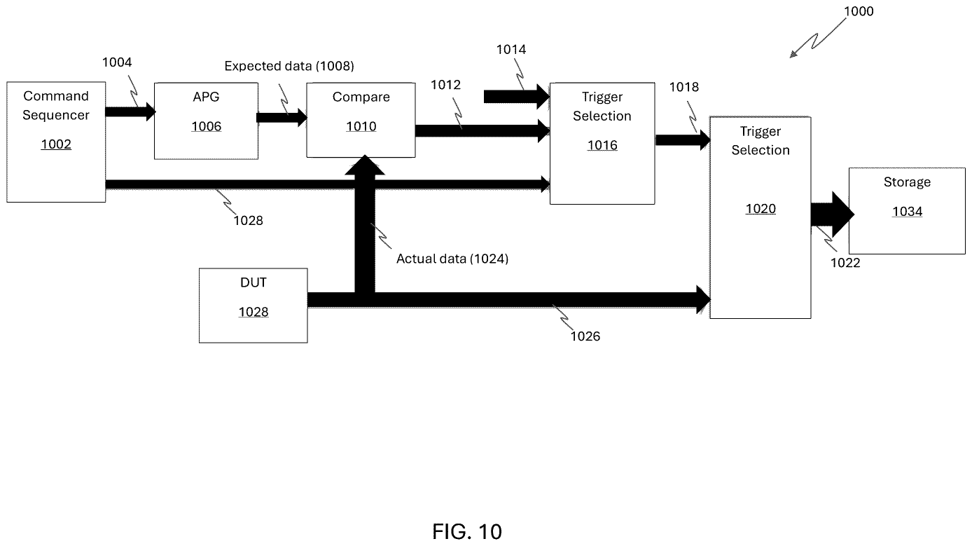

In the example of FIG. 10, command sequencer 1002 implemented on exemplary FPGA 1000 of a test system generates or accesses a series of commands for performing device testing on one or more DUTs in accordance with one embodiment of the present invention. Commands from the test sequence are carried over channel 1028. Command sequencer 1002 controls automatic pattern generator 1006 to generate patterns according to the series of commands 1004. The expected data 1008 is compared with protocol data actually read 1024 from a DUT by the test system at step 1010. When compare module 1010 identifies a mismatch between expected data 1008 and the data actually read 1024, a compare error 1012 is provided to trigger selection 1016 module, as well as any other triggers 1014 mentioned above (e.g., system events, sideband signals, etc.). Moreover, commands sequencer 1002 can transmit specific command-based triggers to triggers selection 1016 to activate a trigger based on a command of a test sequence over channel 1028, for example, and the trigger can activate at a specific place or command issued in the test sequence. The command-based triggers can be programmed by a test engineer prior to testing as part of a test sequence, for example.

Trigger selection module 1016 can be configured to issue a trigger 1018 to capture control 1020 based on any number of different criteria, including the detection of certain command sequences, system events, or instructions, or based on a mismatch between expected data 1008 and data actually read 1024 from DUT 1028 as described above. When a trigger 1018 is provided to capture control module 1020, protocol data 1026 can be captured as capture data 1022 and provided to storage module 1034 for storage, and the capture data 1022 can be analyzed for testing or debugging purposes, for example.

The exemplary embodiment of FIG. 10 is especially useful for issuing triggers during the execution of a test sequence based on test activity or tester-generated conditions, for example, when a mismatch is detected between expected data 1008 and data actually read 1024. Advantageously, the test system can respond to any tester-generated error condition or other test pattern or sequence in real-time to issue a trigger 1018 from trigger selection module 1016. Moreover, trigger selection module 1016 can issue a trigger 1018 at a specific place in the test sequence when the test sequence includes an ordered sequence of operations as carried over channel 1028. Upon receiving trigger 1018, capture control module 1020 begins capturing protocol data 1026 (and likewise sideband data) and stores the captured data 1022 in storage module 1024. The stored data can be evaluated for debugging purposes, for example. Alternatively, capture control module 1020 can be configured to capture protocol data 1026 from DUT 1028 continuously until a specific signal, command, or pattern of data is received from trigger selection module 1016 that causes the capture control module 1020 to stop capturing data.

### Memory Pooling for Increased Capture Depth

According to some embodiments, FPGAs are each connected to their own dedicated memory block as discussed above. These memory blocks can be utilized, among other things, to store the test pattern data that is written out to the DUTs during testing. In one embodiment, each of the FPGA devices can include two instantiated FPGA tester blocks (e.g., instantiated FPGA tester blocks 210A and 210B of FIG. 2) with functional modules for performing functions including implementation of communicative protocol engines and hardware accelerators. In other embodiments, each FPGA device may comprise multiple instantiated FPGA tester blocks. Memory blocks can each contain one or more memory modules, wherein each memory module within the memory block can be dedicated to one or more of the instantiated FPGA tester blocks. Accordingly, each of the instantiated FPGA tester blocks can be connected to its own dedicated or allocated memory module within a memory block, and the memory can be allocated to a DUT for testing and debugging purposes. In another embodiment, instantiated FPGA tester blocks can share one of the memory modules within a memory block. In a different embodiment, each FPGA device can have multiple instantiated FPGA tester blocks, each with a respective memory block.

Although each tester has its own memory block per DUT, if not all DUTs are being debugged using the IPA, the “unused” memories may be pooled to afford a larger capture depth for a limited number of DUTs that are actively being tested. Furthermore, other memory normally used for non-IPA purposes may be included in this memory pool if the DUTs that would ordinarily use that memory are not being tested at all. For example, if four DUTs are coupled to an instantiated FPGA block, but only one of the DUTs is being tested/debugged, the memory allocated to the inactive DUTs can be pooled and used to store data captured by the IPA. In this way, greater capture depth is available to the IPA during testing which significantly improves testing and debugging efficiency. Moreover, according to some embodiments, memory modules outside of the FPGA that are normally allocated to DUTs for other purposes, such as memory block 240A depicted in FIG. 2, which may be a DRAM module, for example, can be allocated to the IPA to further increase the amount of memory resources available for storing captured data or other testing/debugging purposes for those DUTs being actively tested.

Several approaches to memory pooling and allocation are possible according to various embodiments of the present invention. For example, a DUT can be designated as the “master” DUT that controls the allocation of memory resources normally assigned to other DUTs. Alternatively, a DUT that is currently being tested may be given priority over other DUTs that are not being tested for memory allocation purposes. According to other embodiments, a “wrap around” mode of memory allocation is employed, where a specific DUT (e.g., a DUT currently being tested) is allocated the most resources, the next DUT to be tested is allocated some of the remaining memory resources, and so on, until all memory resources in the memory pool are allocated. Any manner of assigning priority to the various DUTs for memory pooling and allocation purposes can be used, according to embodiments. According to one embodiment, the FPGAs are communicatively coupled by a common communication bus (e.g., a circular bus) to coordinate access to the various memory resources associated with the different DUTs.

As depicted in the block data flow diagram of FIG. 11, exemplary FPGA 1100 includes IPA storage 1124 and non-IPA storage 1122 configured to store captured data using pooled memory resources for testing DUT 1114 according to embodiments of the present invention. By pooling the memory resources of the DUT and/or memory external to FPGA 1100, capture module 1116 can capture data at greater depth for improved testing and debugging efficiency.

Storage manager 1118 can communicate with other storage managers 1120 and 1130 associated with other DUTs for testing and debugging in order to pool memory resources to create a memory pool. In this way, storage manager 1118 can access IPA and non-IPA storage of other instantiated FPGA blocks allocated to the testing of other DUTs, for example, when those DUTs are not being actively tested. Similarly, storage manager 1118 can make non-IPA storage 1122 and IPA storage 1124 available to other storage managers 1120, 1130 in a memory pool for testing and debugging the other DUTs. For example, when DUT 1114 is under test, storage manager 1118 can store protocol data and/or sideband data captured by capture module 1116 in a memory pool that includes non-IPA storage 1122, IPA storage 1124, and/or additional pooled memory resources 1134, 1136 provided by the storage managers 1120, 1130 during testing/debugging of DUT 1114. It should be noted that storage manager 1118 can be in communication with any number of other storage managers coupled to DUTs for pooling memory resources thereof. The memory can be allocated based on priority (e.g., a “master” DUT given the highest priority) or in a wraparound manner where one DUT is assigned a specific amount of memory resources, the next DUT is allocated a portion of the remaining resources, and so on. According to some embodiments, the storage managers of the various FPGAs are all coupled together by a common bus. The common bus can be a circular bus, for example, where each storage manager is coupled to two other storage managers of different FPGAs in a circular manner.

When the testing of DUT 1114 has ended, the memory resources of non-IPA storage 1122 and IPA storage 1124, along with the other memory resources provided by other storage managers (e.g., storage managers 1120, 1130) can be made available for testing other DUTs. The memory resources of non-IPA storage 1122 and IPA storage 1124 can also be made available to storage managers 1120, 1130 for testing other DUTs that are designated as a “master” DUT or a higher priority DUT, for example. As discussed above, capture module 1116 can be configured to capture different types or amounts of data (with other data being filtered out), and the capturing of data can be started or stopped according to one or more triggers generated by hardware accelerator 1102, for example.

As illustrated in FIG. 11, commands over channel 1104 and responses on channel 1106 (e.g., protocol data) transmitted between the accelerator 1102 and the protocol stack 1108 can be provided to capture module 1116 along with the data transmitted over sidebands 1110. The data capture performed by capture module 1116 can be initiated or halted according to one or more triggers 1132 (e.g., system events) received from accelerator 1102, including commands 1104 and response 1106, or based on the detection of a predetermined signal or pattern of data identified in sidebands 1110. Importantly, both the protocol data and the sideband data can be captured in real-time by capture module 1116, and the relationship between the protocol data and the sideband data can be analyzed for debugging purposes.

### Sideband Signal Generation and Operation

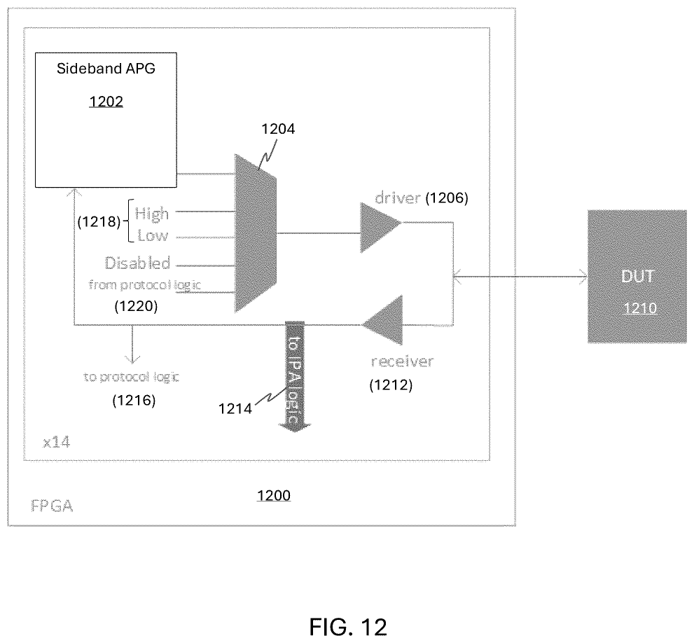

FIG. 12 is a block diagram depicting an exemplary FPGA 1200 coupled to a DUT 1210 for testing and debugging using sideband signals to operate and/or configure DUT 1210 in accordance with one embodiment of the present invention. In the example of FIG. 12, sideband signals are generated by sideband automatic pattern generator 1202. The signals and data generated by sideband APG 1202 typically include relatively slow-speed signals (e.g., less than 1 GHz) for configuring and operating DUT 1210, such as reset signals, clock enable signals, low power mode signals, PCIe signals, interface configuration signals, wake signals, clock reset signals, etc. These signals are typically generated by sideband APG 1202 and transmitted to DUT 1210 for execution, although some sideband signals can be generated by DUT 1210 and transmitted to FPGA 1200 (e.g., system clock enable signals). The sideband signals received by FPGA 1200 from DUT 1210 are provided to receiver 1212 and thereafter can be distributed to IPA logic 1214, to protocol logic 1216, and/or to sideband APG 1202. IPA logic 1214 can capture and filter the data output by multiplexer 1204 or received from DUT 1210, and the captured data can be analyzed to identify triggers as discussed above.

As illustrated in FIG. 12, multiplexer 1204 is coupled to sideband APG 1202 and can selectively route signals from sideband APG 1202, static values 1218 (high/low), or data from protocol logic 1220 to driver 1206 for transmission to DUT 1210. In this way, the sideband communications may be selectively driven using the sideband APG 1202, static software-set levels 1218, or data from serial protocol logic 1220, as desired during testing and debugging of DUT 1210. Importantly, both sideband and protocol data can be captured simultaneously and used for triggering purposes, as discussed above. Moreover, the relationship between the sideband and the protocol data can be captured, stored, and evaluated for debugging purposes advantageously to improve testing and debugging efficiency. In some embodiments, memory allocated to DUT 1210 can be pooled and made available for capturing sideband and protocol data generated when testing other DUTs, and FPGA 1200 can access the pooled memory during testing of DUT 1210. In one embodiment, DUT 1210 is designated as a master DUT for memory pooling purposes.

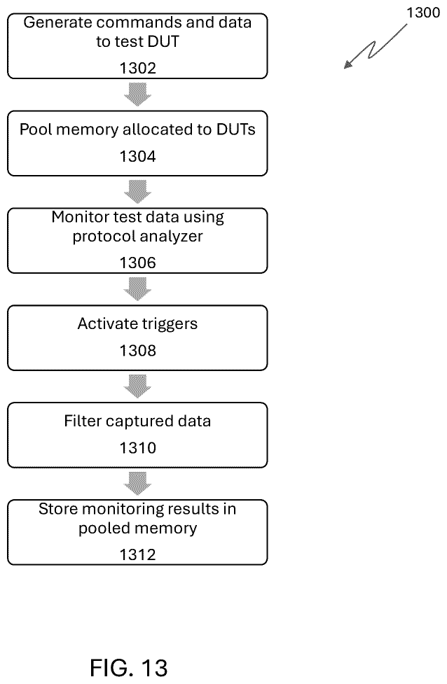

FIG. 13 illustrates a flowchart of an exemplary computer implemented process 1300 for monitoring and capturing communications (e.g., DUT test data) between a programmable logic device and a DUT, and storing the captured data in pooled memory that includes memory normally allocated to other DUTs in accordance with one embodiment of the present invention. For example, test equipment (e.g., an ATE) can be coupled to four DUTs for testing, wherein only one of the DUTs is testing at a time. Accordingly, memory allocated to the three “inactive” DUTs can be pooled together and made available to the IPA allocated to the actively tested DUT to store captured data. The captured data can include protocol data as well as sideband data, and the captured data can be monitored or analyzed to identify important system events, capture commands, data mismatches, etc., and the identified events or commands can cause one or more triggers to be issued, for example, by a trigger module of the IPA. The triggers typically cause one or more actions to be taken by the IPA or another test system component.

At step 1302, a programmable logic device, such as an FPGA, is controlled or programmed to generate commands and data to test the DUT, wherein an interface core and a protocol analyzer module have been programmed onto the programmable logic device. The interface core generates signals to communicate with the DUT using a protocol associated with the DUT, and the system controller controls a test program to test a plurality of DUTs coupled to the system controller. Typically each of the DUTs are allocated with a respective dedicated memory.

At step 1304, the dedicated memory normally allocated to the DUTs coupled to the system controller is pooled together in a pooled memory space by the storage manager. Step 1304 can include storage managers allocated to the respective DUTs coordinating the storage of captured test data, for example, and the pooled memory can include IPA and non-IPA storage.

At step 1306, data generated during testing is monitored and/or captured by the protocol analyzer. The monitored data can include protocol data, sideband data, system events, identified patterns, identified mismatches, etc. Typically the monitored data is generated by the programmable logic device and transmitted to the DUT, although some captured data can be generated by the DUT and transmitted to the programmable logic device.

At step 1308, some or all of the data monitored can be captured according to one or more triggers that cause the protocol analyzer to start or stop capturing data. The triggers can include specific command-based triggers issued during the execution of a test sequence, system event triggers (e.g., data mismatch), or triggers based on sideband or protocol signals or data patterns, for example.

At step 1310, captured data can be filtered according to predetermined criteria to preserve memory resources.

At step 1312, results of the capturing performed in step 1308 are advantageously stored in the pooled memory space. Step 1312 can include storage managers coupled to the system controller coordinating storage of data using various memories normally allocated to different DUTs, when those DUTs are not under test, or when those DUTs are designated a lower priority that the DUT currently being tested/debugged, for example. By pooling the available memory in this way, greater capture depth is afforded to the system controller for debugging purposes for the actively tested DUTs, which improves the speed and efficiency of the debugging without requiring additional resources being assigned to the system controller. In other words, existing resources are advantageously repurposed to improve capture depth and improve debugging performance.

In sum, the disclosed techniques overcome the limitations of traditional methods by providing increased capture depth of monitored protocol and sideband data by pooling memory resources allocated to different DUTs. In this way, actively tested DUTs can advantageously use the allocated memory of inactive DUTs for capture storage. Furthermore, the capturing and storing can be triggered based on sideband activity, or based on commands or system events, for example, which improves testing flexibility and efficiency compared to traditional methods. Triggering on sideband information can cause the capture of both sideband and protocol data simultaneously, which can aid in debugging. Also, triggering on system events, e.g., data mismatch, also increases debugging effectiveness. In addition to triggering on system events, trigger logic can also be programmed to respond to prescribed commands of the test sequence.

At least one technical advantage of the disclosed techniques is that existing resources can be repurposed as a result of memory pooling to improve capture depth and data monitoring efficiency during testing. For example, commands to capture data can be programmed into a test sequence at a specific place in the sequence, and the captured data can be filtered based on predetermined criteria to conserve memory resources.
1. In some embodiments, a method of monitoring communications between a tester processor and a plurality of devices under test (DUTs) comprises with respect to an interface core and a protocol analyzer module that have been programmed onto a programmable logic device allocated to a first DUT of said plurality of DUTs, controlling the programmable logic device by a tester processor to generate commands and data to test the first DUT, wherein the interface core is operable to generate signals to communicate with the first DUT using a protocol associated with the first DUT, and wherein the tester processor is also operable to control a test program for testing the plurality DUTs coupled to the tester processor, wherein each of the plurality DUTs is allocated a respective allocated memory, a respective protocol analyzer module, and a respective interface core, pooling together a plurality of allocated memories of the plurality of DUTs in a pooled memory space, during testing of the first DUT, monitoring data and command traffic communicated between the first DUT and the programmable logic device allocated to the first DUT using the protocol analyzer module allocated to the first DUT, and storing results associated with the monitoring in the pooled memory space wherein memory storage of said plurality of allocated memories allocated to DUTs, of said plurality of DUTs, that are not under test is made available in the pooled memory space for storage resultant from the testing of the first DUT to increase storage capacity therefor.
2. The method of clause 1, wherein the results comprise protocol dataprotocol data and sideband data resultant from the testing of the first DUT.
3. The method of clause 2, further comprising transmitting the results upon request to an application program associated with the protocol analyzer module executing on the tester processor.
4. The method of any of clauses 1 through 3, wherein the programmable logic device comprises a Field Programmable Gate Array (FPGA).
5. The method of any of clauses 1 through 4, wherein the monitoring data and command traffic comprises monitoring sideband data communicated between the programmable logic device and the first DUT.
6. The method of any of clauses 1 through 5, wherein the protocol analyzer module comprises a filtering module, and wherein the monitoring comprises, prior to the storing, filtering unwanted subsets of the sideband data from the data and command traffic using the filtering module.
7. The method of any of clauses 1 through 6, wherein the protocol analyzer module comprises a triggering module, and wherein the monitoring comprises prior to the storing, using the triggering module to recognize prescribed patterns of the sideband data in the data and command traffic, and performing actions in response to the triggering module recognizing patterns of the sideband data of data in the data and command traffic.
8. The method of any of clauses 1 through 4, wherein the monitoring data and command traffic comprises monitoring sideband data communicated between the programmable logic device and the first DUT, wherein the protocol analyzer module comprises a triggering module, and wherein the monitoring comprises prior to the storing, using the triggering module to recognize prescribed patterns of data in the sideband data, and performing actions in response to the triggering module recognizing patterns of data in the sideband data.
9. The method of any of clauses 1 through 6, wherein the protocol analyzer module comprises a triggering module, and wherein the monitoring comprises prior to the storing, using the triggering module to recognize system event comprising a mismatch between actual data retrieved from the first DUT and expected data, and performing actions in response to the triggering module recognizing the system event.
10. The method of any of clauses 1 through 6, wherein the protocol analyzer module comprises a triggering module, and wherein the monitoring comprises prior to the storing, using the triggering module for recognizing at least one of a system event, and a command from a test sequence, and performing actions in response to the recognizing.
11. The method of any of clauses 1 through 10, wherein the first DUT comprises a master DUT, and wherein the pooled memory space comprises memory allocated to DUTs of the plurality of DUTs that are not master DUTs.
12. The method of any of clauses 1 through 10, wherein the pooled memory space comprises memory allocated to DUTs of the plurality of DUTs that are a lower priority than the first DUT.
13. In some embodiments, an apparatus for diagnosing a cause of failure using automated test equipment (ATE), the apparatus comprises a computer system communicatively coupled to a site module board comprising a tester processor and a programmable logic device, wherein the tester processor is operable to transmit instructions to perform tests on a plurality of devices under test (DUTs) coupled to the tester processor and the programmable logic device, wherein each of the plurality DUTs is allocated a respective allocated memory, a respective protocol analyzer module, and a respective interface core, and wherein the tester processor is operable to pool together a plurality of allocated memories of the plurality of DUTs in a pooled memory space, and the programmable logic device operable to be communicatively coupled to a first DUT of the plurality of DUTs and operable to generate commands and data for testing of the first DUT, wherein the programmable logic device comprises a protocol analyzer module for monitoring data and command traffic communicated between the programmable logic device and the first DUT, and wherein the programmable logic device is operable for storing results associated with the monitoring in the pooled memory space and wherein storage of allocated memories allocated to DUTs of said plurality of DUTs that are not under test is made available for use for the testing of the first DUT.
14. The apparatus of clause 13, wherein the monitoring data and command traffic comprises monitoring sideband data, triggering based on recognized sideband data, and filtering information from said sideband data to produce filtered data, and wherein said storing results comprises storing the filtered data and wherein further the programmable logic device is operable to transmit the results to an application program associated with the protocol analyzer module executing on the tester processor.
15. The apparatus of clause 13, wherein the monitoring data and command traffic comprises monitoring system events, triggering based on recognized system events, and filtering information from said data and command traffic to produce filtered data, and wherein said storing results comprises storing the filtered data and wherein further the programmable logic device is operable to transmit the results to an application program associated with the protocol analyzer module executing on the tester processor.
16. The apparatus of clause 15, wherein a recognized system event is a mismatch between actual data retrieved from the first DUT and expected data.
17. The apparatus of any of clauses 13 through 16, wherein the programmable logic device comprises a Field Programmable Gate Array (FPGA), and wherein the plurality of allocated memories is implemented on the FPGA.
18. In some embodiments, a tester comprises a system controller for executing a test program for testing a plurality of DUTs, a plurality of modules coupled to the system controller and operable to interface with and test the plurality of DUTs, wherein each module comprises a site module board, wherein each DUT of the plurality of DUTs are allocated memory controlled by a storage manager, and wherein each site module board comprises a tester processor coupled to communicate with the system controller to receive instructions and data therefrom in accordance with the test program, wherein the storage manager is operable to pool together a plurality of allocated memories of the plurality of DUTs in a pooled memory, and a plurality of programmable logic devices coupled to the tester processor, each programmable logic device comprising an interface core and operable to generate test data for application to a respective DUT, and to receive and to compare test data generated by the respective DUT, and wherein the interface core of each programmable logic device is operable to be programmed to communicate with the respective DUT using a communication protocol compatible with the respective DUT, and wherein each of the programmable logic devices comprises a protocol analyzer module, and wherein the protocol analyzer module is programmed for monitoring data and command traffic associated with the protocol in the interface core and for storing results associated with the monitoring in the pooled memory, and wherein storage of the pooled memory that is allocated to DUTs of said plurality of DUTs that are not under test is made available for the testing of other DUTs.
19. The tester of clause 18, wherein the storage manager utilizes a circular bus to implement said pooled memory and wherein the data and command traffic comprise sideband data and wherein further said monitoring comprises triggering on prescribed data of the sideband data.
20. The tester of clause 18, wherein the storage manager utilizes a circular bus to implement said pooled memory and wherein the data and command traffic comprise system events and wherein further said monitoring comprises triggering on prescribed events of the system events.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer. ” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), digital video disc (DVD), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. While the preceding is directed to embodiments of the present disclosure, other and further embodiments of the disclosure may be devised without departing from the basic scope thereof, and the scope thereof is determined by the claims that follow.

Embodiments of the present invention are thus described. While the present invention has been described in particular embodiments, it should be appreciated that the present invention should not be construed as limited by such embodiments, but rather construed according to the following claims.

What is claimed is:

1. A method of monitoring communications between a tester processor and a plurality of devices under test (DUTs), the method comprising:
with respect to an interface core and a protocol analyzer module that have been programmed onto a programmable logic device allocated to a first DUT of said plurality of DUTs, controlling the programmable logic device by a tester processor to generate commands and data to test the first DUT, wherein the interface core is operable to generate signals to communicate with the first DUT using a protocol associated with the first DUT, and wherein the tester processor is also operable to control a test program for testing the plurality DUTs coupled to the tester processor, wherein each of the plurality DUTs is allocated: a respective allocated memory; a respective protocol analyzer module; and a respective interface core;
pooling together a plurality of allocated memories of the plurality of DUTs in a pooled memory space;
during testing of the first DUT, monitoring data and command traffic communicated between the first DUT and the programmable logic device allocated to the first DUT using the protocol analyzer module allocated to the first DUT; and
storing results associated with the monitoring in the pooled memory space wherein memory storage of said plurality of allocated memories allocated to DUTs, of said plurality of DUTs, that are not under test is made available in the pooled memory space for storage resultant from the testing of the first DUT to increase storage capacity thereof.

2. The method of claim 1, wherein the results comprise protocol data and sideband data resultant from the testing of the first DUT.

3. The method of claim 2, further comprising transmitting the results upon request to an application program associated with the protocol analyzer module.

4. The method of claim 1, wherein the programmable logic device comprises a Field Programmable Gate Array (FPGA).

5. The method of claim 1, wherein the monitoring data and command traffic comprises monitoring sideband data communicated between the programmable logic device and the first DUT.

6. The method of claim 5, wherein the protocol analyzer module comprises a filtering module, and wherein the monitoring further comprises, prior to the storing, filtering unwanted subsets of the sideband data from the data and command traffic using the filtering module.

7. The method of claim 5, wherein the protocol analyzer module comprises a triggering module, and wherein the monitoring comprises:
prior to the storing, using the triggering module to recognize prescribed patterns of the sideband data in the data and command traffic; and
performing actions in response to the triggering module recognizing patterns of the sideband data in the data and command traffic.

8. The method of claim 1, wherein the monitoring data and command traffic comprises monitoring sideband data communicated between the programmable logic device and the first DUT, wherein the protocol analyzer module comprises a triggering module, and wherein the monitoring comprises:
prior to the storing, using the triggering module to recognize prescribed patterns of data in the sideband data; and
performing actions in response to the triggering module recognizing patterns of data in the sideband data.

9. The method of claim 1, wherein the protocol analyzer module comprises a triggering module, and wherein the monitoring comprises:
prior to the storing, using the triggering module to recognize a system event comprising a mismatch between actual data retrieved from the first DUT and expected data; and
performing actions in response to the triggering module recognizing the system event.

10. The method of claim 1, wherein the protocol analyzer module comprises a triggering module, and wherein the monitoring comprises:
prior to the storing, using the triggering module for recognizing at least one of: a system event; and a command from a test sequence; and
performing actions in response to the recognizing.

11. The method of claim 1, wherein the first DUT comprises a master DUT, and wherein the pooled memory space comprises memory allocated to DUTs of the plurality of DUTs that are not master DUTs.

12. The method of claim 1, wherein the pooled memory space comprises memory allocated to DUTs of the plurality of DUTs that are a lower priority than the first DUT.

13. An apparatus for diagnosing a cause of failure using automated test equipment (ATE), the apparatus comprising:
a computer system communicatively coupled to a site module board comprising a tester processor and a programmable logic device, wherein the tester processor is operable to transmit instructions to perform tests on a plurality of devices under test (DUTs) coupled to the tester processor and the programmable logic device, wherein each of the plurality DUTs is allocated: a respective allocated memory; a respective protocol analyzer module; and a respective interface core, and wherein the tester processor is operable to pool together a plurality of allocated memories of the plurality of DUTs in a pooled memory space; and
the programmable logic device operable to be communicatively coupled to a first DUT of the plurality of DUTs and operable to generate commands and data for testing of the first DUT, wherein the programmable logic device comprises a protocol analyzer module for monitoring data and command traffic communicated between the programmable logic device and the first DUT, and
wherein the programmable logic device is operable for storing results associated with the monitoring in the pooled memory space and wherein storage of allocated memories allocated to DUTs of said plurality of DUTs that are not under test is made available for use for the testing of the first DUT.

14. The apparatus of claim 13, wherein the monitoring data and command traffic comprises:
monitoring sideband data;
triggering based on recognized sideband data; and
filtering information from said sideband data to produce filtered data; and
wherein said storing results comprises storing the filtered data and wherein further the programmable logic device is operable to transmit the results to an application program associated with the protocol analyzer module executing on the tester processor.

15. The apparatus of claim 13, wherein the monitoring data and command traffic comprises:
monitoring system events;
triggering based on recognized system events; and
filtering information from said data and command traffic to produce filtered data; and wherein said storing results comprises storing the filtered data and wherein further the programmable logic device is operable to transmit the results to an application program associated with the protocol analyzer module executing on the tester processor.

16. The apparatus of claim 15, wherein a recognized system event is a mismatch between actual data retrieved from the first DUT and expected data.

17. The apparatus of claim 13, wherein the programmable logic device comprises a Field Programmable Gate Array (FPGA), and wherein the plurality of allocated memories is implemented on the FPGA.

18. A tester comprising:
a system controller for executing a test program for testing a plurality of DUTs;
a plurality of modules coupled to the system controller and operable to interface with and test the plurality of DUTs, wherein each module comprises a site module board, wherein each DUT of the plurality of DUTs are allocated memory controlled by a storage manager, and wherein each site module board comprises:
a tester processor coupled to communicate with the system controller to receive instructions and data therefrom in accordance with the test program, wherein the storage manager is operable to pool together a plurality of allocated memories of the plurality of DUTs in a pooled memory; and
a plurality of programmable logic devices coupled to the tester processor, each programmable logic device comprising an interface core and operable to generate test data for application to a respective DUT, and to receive and to compare test data generated by the respective DUT, and wherein the interface core of each programmable logic device is operable to be programmed to communicate with the respective DUT using a communication protocol compatible with the respective DUT, and wherein each of the programmable logic devices comprises a protocol analyzer module, and
wherein the protocol analyzer module is programmed for monitoring data and command traffic associated with the protocol in the interface core and for storing results associated with the monitoring in the pooled memory, and wherein storage of the pooled memory that is allocated to DUTs of said plurality of DUTs that are not under test is made available for the testing of other DUTs.

19. The tester of claim 18, wherein the storage manager utilizes a circular bus to implement said pooled memory and wherein the data and command traffic comprise sideband data and wherein further said monitoring comprises triggering on prescribed data of the sideband data.

20. The tester of claim 18, wherein the storage manager utilizes a circular bus to implement said pooled memory and wherein the data and command traffic comprise system events and wherein further said monitoring comprises triggering on prescribed events of the system events.
